(19) United States
(12) Patent Application Publication
(10) Pub. No.: US 2024/0387583 A1
(43) Pub. Date: Nov. 21, 2024

(54) PHOTODETECTOR AND ELECTRONIC APPARATUS

(71) Applicant: SONY SEMICONDUCTOR SOLUTIONS CORPORATION, Kanagawa (JP)

(72) Inventors: Kazuya FURUMOTO, Kanagawa (JP); Shinji NAKAGAWA, Kanagawa (JP); Michiko SAKAMOTO, Kanagawa (JP); Jun KUROIWA, Kanagawa (JP); Tadashi IIJIMA, Kanagawa (JP); Tetsuya MINAKAWA, Kanagawa (JP)

(73) Assignee: SONY SEMICONDUCTOR SOLUTIONS CORPORATION, Kanagawa (JP)

(21) Appl. No.: 18/692,499

(22) PCT Filed: Mar. 24, 2022
(86) PCT No.: PCT/JP2022/013973

§ 371 Date: Mar. 15, 2024

(30) Foreign Application Priority Data
Sep. 30, 2021 (JP) 2021-160953

(51) Int. Cl. H01L 27/146

(52) U.S. Cl. CPC H01L 27/14627; H01L 27/14605; H01L 27/14621

(57) ABSTRACT

The present disclosure relates to a photodetector and an electronic apparatus that can enhance their performance. Provided is a photodetector including multiple pixels each having a photoelectric conversion region, and an on-chip micro lens disposed for the pixels. In at least a part of a pixel section including n×n pixels, a first on-chip micro lens and a second on-chip micro lens different from the first on-chip micro lens are disposed. The present disclosure can be applied to CMOS solid-state image pickup devices, for example.

### TECHNICAL FIELD

The present disclosure relates to a photodetector and an electronic apparatus, in particular, to a photodetector and an electronic apparatus that can enhance their performance.

### BACKGROUND ART

In solid-state image pickup devices, a structure in which a single on-chip micro lens (hereinafter also referred to as an “OCL”) is shared by multiple pixels of the same color has been known (for example, see PTL 1).

### CITATION LIST

### Patent Literature

PTL 1: U.S. Patent Application Publication No. 2021/0144315

### SUMMARY

### Technical Problem

However, the technology disclosed in PTL 1 has a possibility of failing to obtain sufficient performance when using a structure in which a single on-chip micro lens is shared by multiple pixels of the same color, and there is a demand for enhancing the performance. The present disclosure has been made in view of such a circumstance and aims to achieve performance enhancement.

### Solution to Problem

A photodetector according to an aspect of the present disclosure is a photodetector including multiple pixels each having a photoelectric conversion region, and an on-chip micro lens disposed for the pixels. In at least a part of a pixel section including n×n pixels, a first on-chip micro lens and a second on-chip micro lens different from the first on-chip micro lens are disposed.

An electronic apparatus according to an aspect of the present disclosure is an electronic apparatus having a photodetector mounted thereon, the photodetector including multiple pixels each having a photoelectric conversion region, and an on-chip micro lens disposed for the pixels. In at least a part of a pixel section including n×n pixels, a first on-chip micro lens and a second on-chip micro lens different from the first on-chip micro lens are disposed.

In a photodetector and an electronic apparatus according to an aspect of the present disclosure, multiple pixels each having a photoelectric conversion region and an on-chip micro lens disposed for the pixels are provided, and in at least a part of a pixel section including n×n pixels, a first on-chip micro lens and a second on-chip micro lens different from the first on-chip micro lens are disposed.

Note that a photodetector according to an aspect of the present disclosure may be an independent device or an internal block forming a single device.

### BRIEF DESCRIPTION OF DRAWINGS

FIG. 1 is a diagram illustrating a configuration example of a solid-state image pickup device to which the present disclosure is applied.

FIG. 2 is a plan view illustrating a first example of a structure to which the present disclosure is applied.

FIG. 3 is a cross-sectional view corresponding to the plane layout of FIG. 2.

FIG. 4 is a plan view illustrating a second example of the structure to which the present disclosure is applied.

FIG. 5 is a cross-sectional view corresponding to the plane layout of FIG. 4.

FIG. 6 is a plan view illustrating a third example of the structure to which the present disclosure is applied.

FIG. 7 is a cross-sectional view corresponding to the plane layout of FIG. 6.

FIG. 8 is a plan view illustrating a fourth example of the structure to which the present disclosure is applied.

FIG. 9 is a cross-sectional view corresponding to the plane layout of FIG. 8.

FIG. 10 is a plan view illustrating a fifth example of the structure to which the present disclosure is applied.

FIG. 11 is a cross-sectional view corresponding to the plane layout of FIG. 10.

FIG. 12 is a plan view illustrating a sixth example of the structure to which the present disclosure is applied.

FIG. 13 is a cross-sectional view corresponding to the plane layout of FIG. 12.

FIG. 14 is a plan view illustrating a seventh example of the structure to which the present disclosure is applied.

FIG. 15 is a cross-sectional view corresponding to the plane layout of FIG. 14.

FIG. 16 is a plan view illustrating an eighth example of the structure to which the present disclosure is applied.

FIG. 17 is a cross-sectional view corresponding to the plane layout of FIG. 16.

FIG. 18 is a plan view illustrating a ninth example of the structure to which the present disclosure is applied.

FIG. 19 is a cross-sectional view corresponding to the plane layout of FIG. 18.

FIG. 20 is a plan view illustrating a tenth example of the structure to which the present disclosure is applied.

FIG. 21 is a cross-sectional view corresponding to the plane layout of FIG. 20.

FIG. 22 is a plan view illustrating an eleventh example of the structure to which the present disclosure is applied.

FIG. 23 is a cross-sectional view corresponding to the plane layout of FIG. 22.

FIG. 24 is a plan view illustrating a twelfth example of the structure to which the present disclosure is applied.

FIG. 25 is a cross-sectional view corresponding to the plane layout of FIG. 24.

FIG. 26 is a plan view illustrating a thirteenth example of the structure to which the present disclosure is applied.

FIG. 27 is a cross-sectional view corresponding to the plane layout of FIG. 26.

FIG. 28 is a plan view illustrating a fourteenth example of the structure to which the present disclosure is applied.

FIG. 29 is a cross-sectional view corresponding to the plane layout of FIG. 28.

FIG. 30 is a view illustrating an example of a manufacturing method including steps for forming the structure to which the present disclosure is applied.

FIG. 31 is a view illustrating plane layouts corresponding to the cross-sectional views of FIG. 30.

FIG. 32 is a plan view illustrating a first example of a structure to which the present disclosure is applied.

FIG. 33 is a cross-sectional view illustrating effects of the structure to which the present disclosure is applied.

FIG. 34 is a cross-sectional view illustrating the effects of the structure to which the present disclosure is applied.

FIG. 35 is a cross-sectional view illustrating examples of structures of on-chip micro lenses.

FIG. 36 is a cross-sectional view illustrating examples of structures of CF separation sections.

FIG. 37 is a plan view illustrating a second example of the structure to which the present disclosure is applied.

FIG. 38 is a plan view illustrating a third example of the structure to which the present disclosure is applied.

FIG. 39 is a plan view illustrating a fourth example of the structure to which the present disclosure is applied.

FIG. 40 is a plan view illustrating a fifth example of the structure to which the present disclosure is applied.

FIG. 41 is a plan view illustrating a sixth example of the structure to which the present disclosure is applied.

FIG. 42 is a plan view illustrating a seventh example of the structure to which the present disclosure is applied.

FIG. 43 is a plan view illustrating an eighth example of the structure to which the present disclosure is applied.

FIG. 44 is a plan view illustrating a ninth example of the structure to which the present disclosure is applied.

FIG. 45 is a plan view illustrating a tenth example of the structure to which the present disclosure is applied.

FIG. 46 is a plan view illustrating the tenth example of the structure to which the present disclosure is applied.

FIG. 47 is a plan view illustrating the tenth example of the structure to which the present disclosure is applied.

FIG. 48 is a plan view illustrating the tenth example of the structure to which the present disclosure is applied.

FIG. 49 is a plan view illustrating an eleventh example of the structure to which the present disclosure is applied.

FIG. 50 is a plan view illustrating the eleventh example of the structure to which the present disclosure is applied.

FIG. 51 is a plan view illustrating the eleventh example of the structure to which the present disclosure is applied.

FIG. 52 is a plan view illustrating the eleventh example of the structure to which the present disclosure is applied.

FIG. 53 is a plan view illustrating the eleventh example of the structure to which the present disclosure is applied.

FIG. 54 is a plan view illustrating the eleventh example of the structure to which the present disclosure is applied.

FIG. 55 is a plan view illustrating the eleventh example of the structure to which the present disclosure is applied.

FIG. 56 is a block diagram illustrating a configuration example of an electronic apparatus having mounted thereon a photodetector to which the present disclosure is applied.

### DESCRIPTION OF EMBODIMENTS

### (Configuration of Solid-State Image Pickup Device)

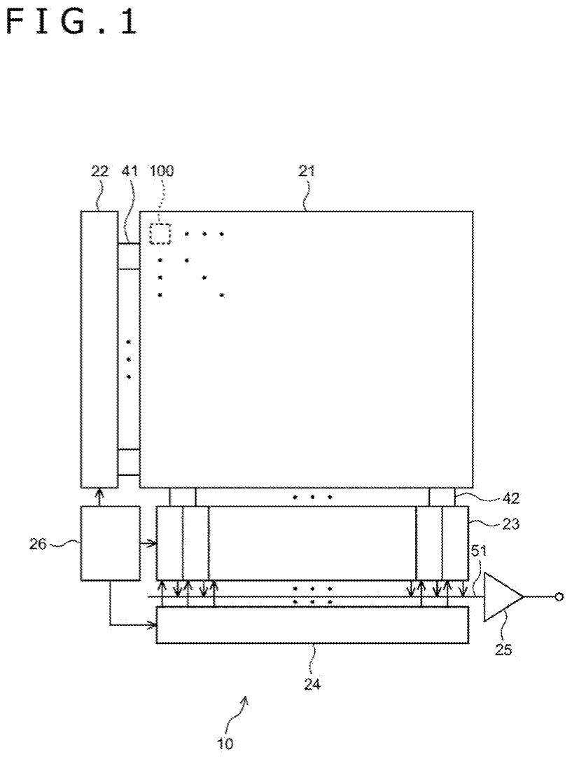

FIG. 1 is a diagram illustrating a configuration example of a solid-state image pickup device to which the present disclosure is applied.

In FIG. 1, a solid-state image pickup device 10 is a CMOS (Complementary Metal Oxide Semiconductor) image sensor. The solid-state image pickup device 10 is an example of a photodetector to which the present disclosure is applied. The solid-state image pickup device 10 includes a pixel array section 21, a vertical drive section 22, signal processing sections 23, a horizontal drive section 24, an output section 25, and a control section 26.

The pixel array section 21 includes multiple pixels 100 arranged in a two-dimensional manner on a substrate including silicon (Si). The pixels 100 each have a photoelectric conversion region including a photodiode (PD).

In the pixel array section 21, for the multiple pixels 100 arranged in a two-dimensional manner, pixel drive lines 41 are formed for the respective rows and connected to the vertical drive section 22, and vertical signal lines 42 are formed for the respective columns and connected to the signal processing sections 23.

The vertical drive section 22 includes a shift register, an address decoder, or the like and drives each of the pixels 100 arranged in the pixel array section 21. Pixel signals output from the pixels 100 selectively scanned by the vertical drive section 22 are supplied to the signal processing sections 23 through the vertical signal lines 42.

The signal processing sections 23 each perform predetermined signal processing on pixel signals output from each of the pixels 100 in the selected row through the vertical signal line 42, for each pixel column of the pixel array section 21. As the signal processing, for example, readout processing and denoising processing are performed.

The horizontal drive section 24 includes a shift register, an address decoder, or the like and sequentially selects unit circuits corresponding to the pixel columns of the signal processing sections 23. Through selective scanning by the horizontal drive section 24, pixel signals subjected to signal processing by the signal processing sections 23 are output to the output section 25 through a horizontal signal line 51.

The output section 25 performs predetermined signal processing on pixel signals sequentially input from each of the signal processing sections 23 through the horizontal signal line 51 and outputs the signals thus obtained.

The control section 26 includes a timing generator or the like configured to generate various timing signals. The control section 26 performs, on the basis of various timing signals generated by the timing generator, drive control of the vertical drive section 22, the signal processing sections 23, the horizontal drive section 24, and the like.

### 1. First Embodiment

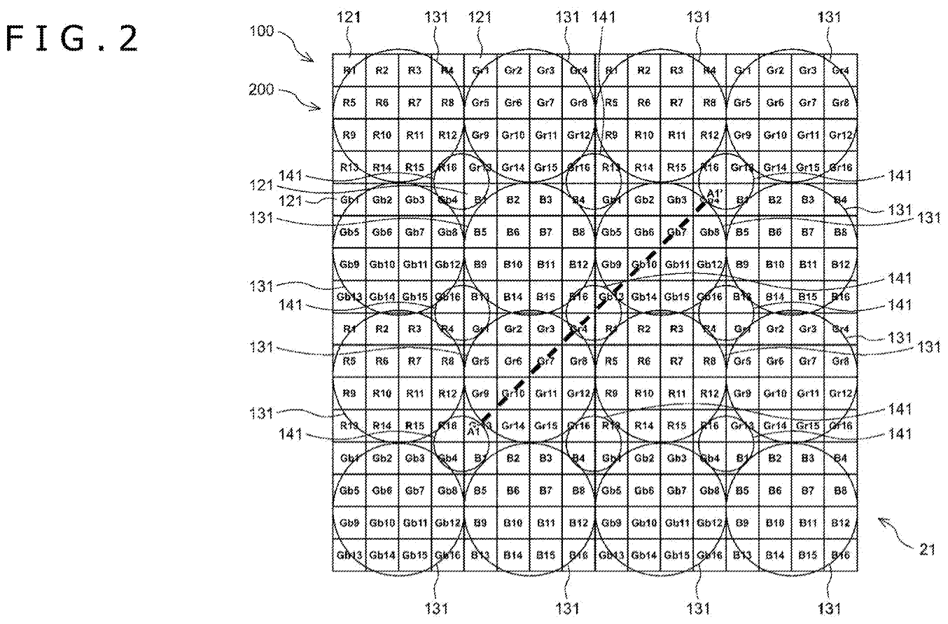

Next, with reference to FIG. 2 to FIG. 31, an example (first embodiment) of a structure including the pixels 100 arranged in a two-dimensional manner in the pixel array section 21 in the solid-state image pickup device 10 is described.

### First Example of Structure

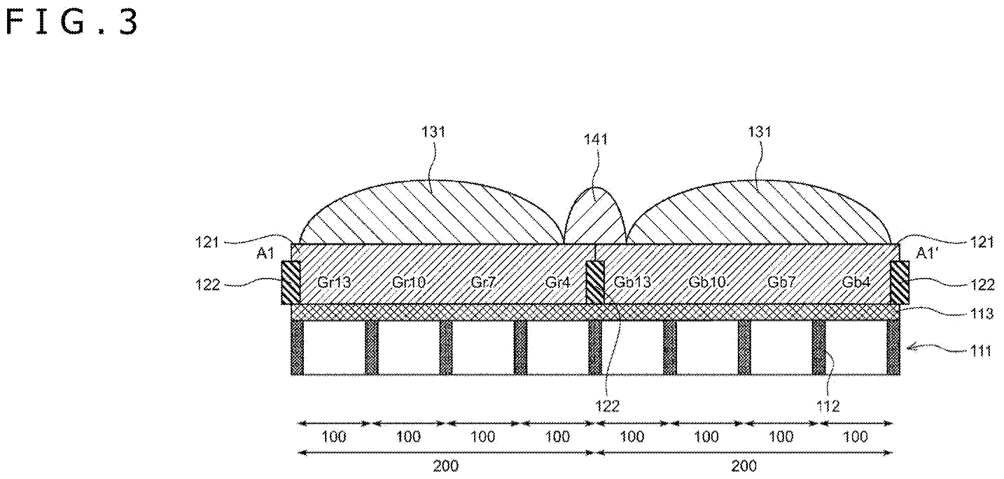

FIG. 2 is a plan view illustrating a first example of a structure to which the present disclosure is applied. FIG. 3 is a cross-sectional view illustrating a cross section A1-A1′ in the plane layout of FIG. 2.

In FIG. 2, each of squares disposed in the row and column directions represents the pixel 100, and for each of the pixels 100, a color filter 121 corresponding to red (R), green (G), or blue (B) is disposed.

In FIG. 2, for the sake of description, identification information that combines abbreviations representing the colors of the color filters 121, namely, “R,” “Gr,” “Gb,” and “B,” with numbers for identifying each region is described in regions corresponding to the color filters 121 disposed for the pixels 100. Also in FIG. 3, the identification information that combines the abbreviations representing the colors with the numbers is described in regions corresponding to the color filters 121.

Sixteen (4×4) pixels provided with R color filters 121-R1 to R16 configured to transmit a wavelength corresponding to red (R) are configured as R pixels. Sixteen (4×4) pixels provided with G color filters 121-Gr1 to Gr16 configured to transmit a wavelength corresponding to green (G) are configured as Gr pixels. Sixteen (4×4) pixels provided with G color filters 121-Gb1 to Gb16 are configured as Gb pixels. Sixteen (4×4) pixels provided with B color filters 121-B1 to B16 configured to transmit a wavelength corresponding to blue (B) are configured as B pixels.

In FIG. 2, pixel sections 200 each include the 16 (4×4) pixels 100 provided with the color filters 121 of the same color. Specifically, the 4×4 R pixels form an R pixel section. The 4×4 Gr pixels form a Gr pixel section, and the 4×4 Gb pixels form a Gb pixel section. The 4×4 B pixels form a B pixel section.

In the pixel array section 21, the R pixel sections, the Gr pixel sections, the Gb pixel sections, and the B pixel sections are regularly arranged in a Bayer array. A Bayer array is an array pattern in which G pixels are disposed in a checkered pattern, and R pixels and B pixels are alternately disposed in each column in the remaining portions. The array pattern illustrated in FIG. 2 is repeatedly arranged in the pixel array section 21.

A single on-chip micro lens 131 is disposed for the 4×4 R pixels forming each R pixel section. Similarly, with regard to the Gr pixel sections, the Gb pixel sections, and the B pixel sections, the single on-chip micro lens 131 is disposed for the 16 (4×4) pixels forming the pixel section 200 of the corresponding color. In the first embodiment, the structure in which the single on-chip micro lens 131 is shared by the 4×4 pixels 100 (color filters 121 thereof) is also referred to as a “4×4-OCL structure.” The pixel sections 200 with 4×4-OCL structures may be configured as pixel sections (normal pixel sections) configured to generate signals for generating captured images corresponding to light from objects or as pixel sections (phase difference pixel sections) configured to generate signals for performing phase difference detection.

Here, in FIG. 2, when focusing on the R pixel section, the Gr pixel section, the Gb pixel section, and the B pixel section that are the adjacent four pixel sections 200, among the pixel sections 200 disposed in a Bayer array, there is a gap portion that is a region in which the regions of the on-chip micro lenses 131 disposed for the pixel sections 200 of the corresponding colors are absent. Gap portions are regions which are near the on-chip micro lenses 131 and in which the on-chip micro lenses 131 are absent. The pixels 100 in the gap portions have reduced sensitivity.

In FIG. 2, a single on-chip micro lens 141 is disposed in each gap portion near the four on-chip micro lenses 131. This can suppress a reduction in the sensitivity of the pixels 100 in the gap portions.

Specifically, in the plan view of FIG. 2, when focusing on the four pixel sections 200 in the central part, the four pixels including the B pixel provided with the B color filter 121-B16, the Gb pixel provided with the G color filter 121-Gb13, the Gr pixel provided with the G color filter 121-Gr4, and the R pixel provided with the R color filter 121-R1 are located in the gap portion. Thus, in the plan view of FIG. 2, the single on-chip micro lens 141 is disposed for these four (2×2) pixels. In the first embodiment, the structure in which the single on-chip micro lens 141 is shared by the 2×2 pixels 100 (color filters 121 thereof) is also referred to as a “2×2-OCL structure.”

As illustrated in the cross-sectional view of FIG. 3, in each of the Gb pixel section and the Gr pixel section, the single on-chip micro lens 131 is disposed. Further, in the Gb pixel section and the Gr pixel section, the Gb pixel provided with the G color filter 121-Gb13 and the Gr pixel provided with the G color filter 121-Gr4 are partially located in the gap portion, and hence, the on-chip micro lens 141 is disposed on the G color filter 121-Gb13 and the G color filter 121-Gr4.

In this way, although the Gb pixel section and the Gr pixel section have 4×4-OCL structures, since the Gb pixel provided with the G color filter 121-Gb13 and the Gr pixel provided with the G color filter 121-Gr4 are located in the gap portion, those G pixels have a 2×2-OCL structure.

In FIG. 3, the pixels 100 have photoelectric conversion regions formed in a silicon substrate 111. The pixels 100 are separated from other adjacent pixels by pixel separation sections 112. The pixel separation sections 112 include element separation structures such as DTI (Deep Trench Isolation). Further, the color filters 121 of the same color in a 4×4 array, which are disposed to correspond to the pixel section 200 including the 16 (4×4) pixels, are separated from other adjacent color filters by CF separation sections 122. An anti-reflection film 113 is formed on an upper surface of the silicon substrate 111.

As described above, in the first example of the structure, when 4×4-OCL structures are disposed for the pixel sections 200 of the corresponding colors disposed in a Bayer array, the 2×2-OCL structure is disposed in the gap portion located in the central part of every four pixel sections 200, thereby suppressing a reduction in the sensitivity of the pixels 100 located in the gap portions.

Note that, in the first example of the structure, the structure in which the 2×2-OCL structures are disposed in the gap portions has been described, but the structure of the on-chip micro lenses disposed in the gap portions is not limited to a 2×2-OCL structure.

### Second Example of Structure

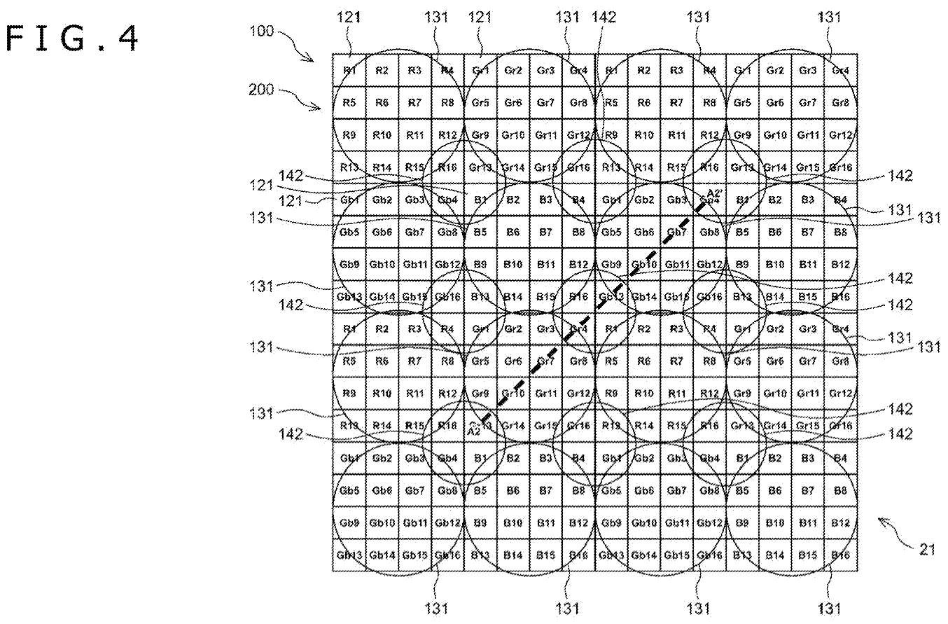

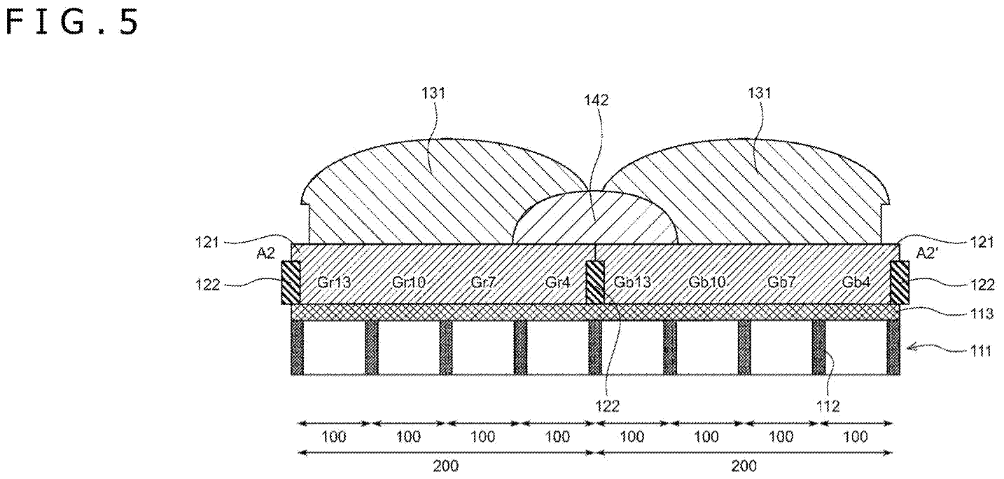

FIG. 4 is a plan view illustrating a second example of the structure to which the present disclosure is applied. FIG. 5 is a cross-sectional view illustrating a cross section A2-A2′ in the plane layout of FIG. 4. In FIG. 4 and FIG. 5, parts corresponding to those of FIG. 2 and FIG. 3 are denoted by the same reference signs, and the descriptions thereof are appropriately omitted. In the following figures, the descriptions of parts with the same reference signs are appropriately omitted as well.

In the structure illustrated in the plane layout of FIG. 4, as compared to the structure illustrated in the plane layout of FIG. 2, inner lenses 142 are disposed in the gap portions due to the 4×4-OCL structures, instead of the on-chip micro lenses 141. In FIG. 4, a single inner lens 142 is disposed in each gap portion near the on-chip micro lens 131 disposed for each of the adjacent four pixel sections 200.

As illustrated in the cross-sectional view of FIG. 5, in each of the Gb pixel section and the Gr pixel section, the single on-chip micro lens 131 is disposed. Further, in the Gb pixel section and the Gr pixel section, the Gb pixel provided with the G color filter 121-Gb13 and the Gr pixel provided with the G color filter 121-Gr4 are partially located in the gap portion, and hence, the inner lens 142 is disposed on the G color filter 121-Gb13 and the G color filter 121-Gr4. The inner lenses 142 are on-chip micro lenses formed inside the on-chip micro lenses 131.

As described above, in the second example of the structure, when 4×4-OCL structures are disposed for the pixel sections 200 of the corresponding colors disposed in a Bayer array, the OCL (inner lens) is disposed in the gap portion located in the central part of every four pixel sections 200, thereby suppressing a reduction in the sensitivity of the pixels 100 located in the gap portions.

Note that, in the second example of the structure, the structure in which the inner lenses are disposed in the gap portions has been described, but all the on-chip micro lenses disposed in the gap portions are not necessarily inner lenses. Some gap portions may be provided with 2×2-OCL structures. That is, a combined structure of the first example of the structure and the second example of the structure may be used.

### Third Example of Structure

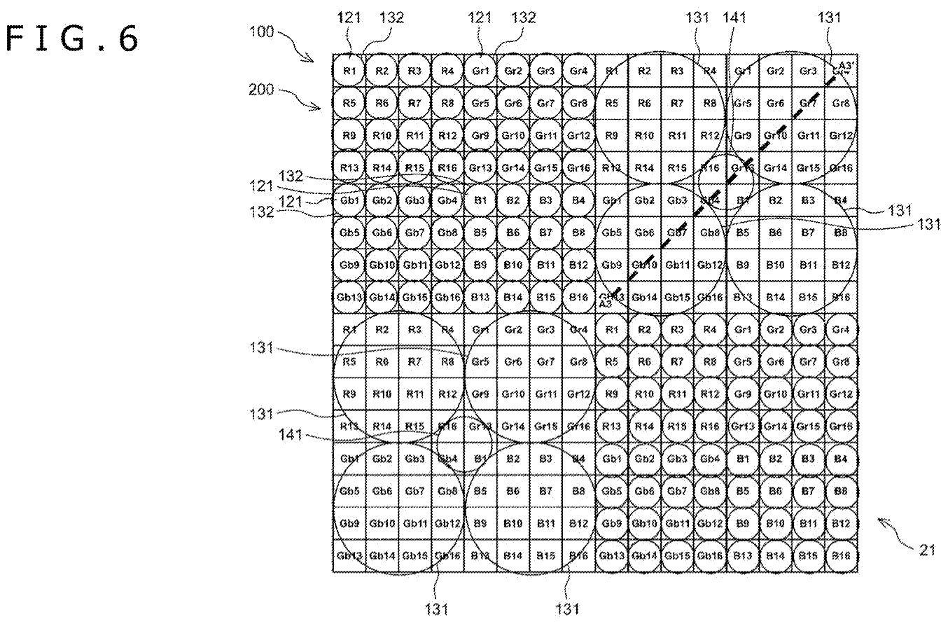

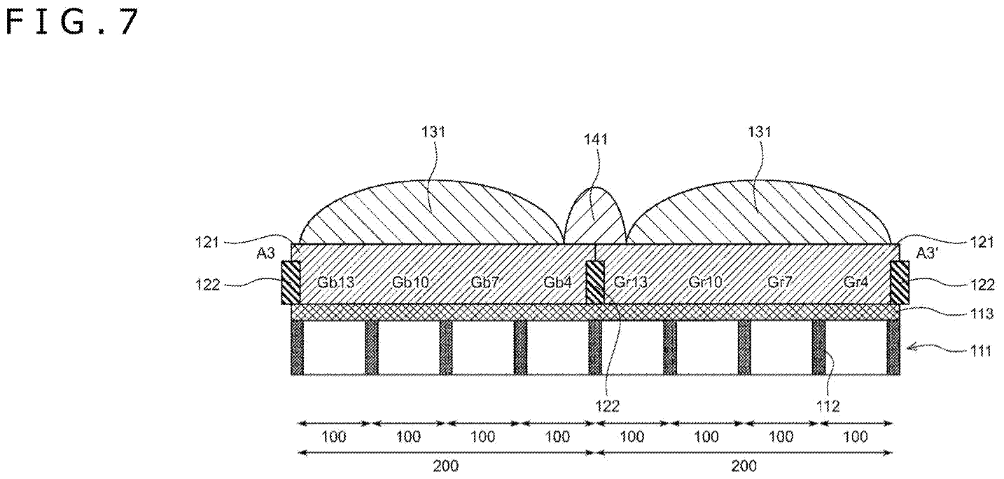

FIG. 6 is a plan view illustrating a third example of the structure to which the present disclosure is applied. FIG. 7 is a cross-sectional view illustrating a cross section A3-A3′ in the plane layout of FIG. 6.

As compared to the structure illustrated in the plane layout of FIG. 2, the structure illustrated in the plane layout of FIG. 6 includes 1×1-OCL structures in addition to the 4×4-OCL structures and is a combined structure of a 4×4-OCL structure and a 1×1-OCL structure.

In FIG. 6, the pixel sections 200 of the corresponding colors, namely, red (R), green (G), and blue (B), are disposed in a Bayer array, and there are regions in which the single on-chip micro lens 131 is disposed for the whole 16 (4×4) pixels forming the pixel section 200 of the corresponding color, and regions in which a single on-chip micro lens 132 is disposed for each pixel forming the pixel sections 200 of the corresponding colors. In the first embodiment, the structure in which the single on-chip micro lens 132 is disposed for the single pixel 100 (color filter 121 thereof) is also referred to as a “1×1-OCL structure.”

That is, when the region illustrated in the plan view of FIG. 6 is divided into four, the four pixel sections 200 in each of the upper-right and lower-left regions have 4×4-OCL structures. Meanwhile, the four pixel sections 200 in each of the upper-left and lower-right regions have 1×1-OCL structures. In the upper-right and lower-left regions, the single on-chip micro lens 141 is disposed in the gap portion that is a region in which the regions of the on-chip micro lenses 131 disposed for the pixel sections 200 of the corresponding colors are absent, thereby forming a 2×2-OCL structure.

As illustrated in the cross-sectional view of FIG. 7, in each of the Gr pixel section and the Gb pixel section, the single on-chip micro lens 131 is disposed. Further, in the Gr pixel section and the Gb pixel section, the Gr pixel provided with the G color filter 121-Gr13 and the Gb pixel provided with the G color filter 121-Gb4 are partially located in the gap portion, and hence, the on-chip micro lens 141 is disposed on the G color filter 121-Gr13 and the G color filter 121-Gb4.

As described above, in the third example of the structure, when combined structures of 4×4-OCL structures and 1×1-OCL structures are applied to the pixel sections 200 of the corresponding colors disposed in a Bayer array, the 2×2-OCL structure is disposed in the gap portion located in the central part of every four pixel sections 200 with a 4×4-OCL structure, thereby suppressing a reduction in the sensitivity of the pixels 100 located in the gap portions. Further, there are cases where, when on-chip micro lenses are disposed after disposing color filters, misalignments occur, that is, the on-chip micro lenses are shifted from the intended positions, but with the combination of a 4×4-OCL structure and a 1×1-OCL structure, even when misalignments occur, it is possible to reduce the influence of the difference in sensitivity between same-color pixels.

### Fourth Example of Structure

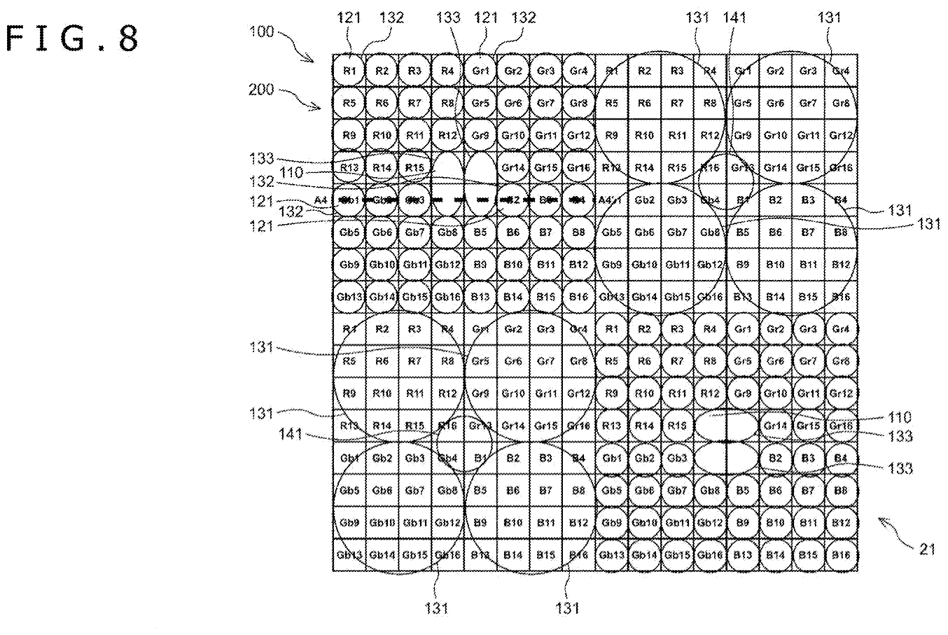

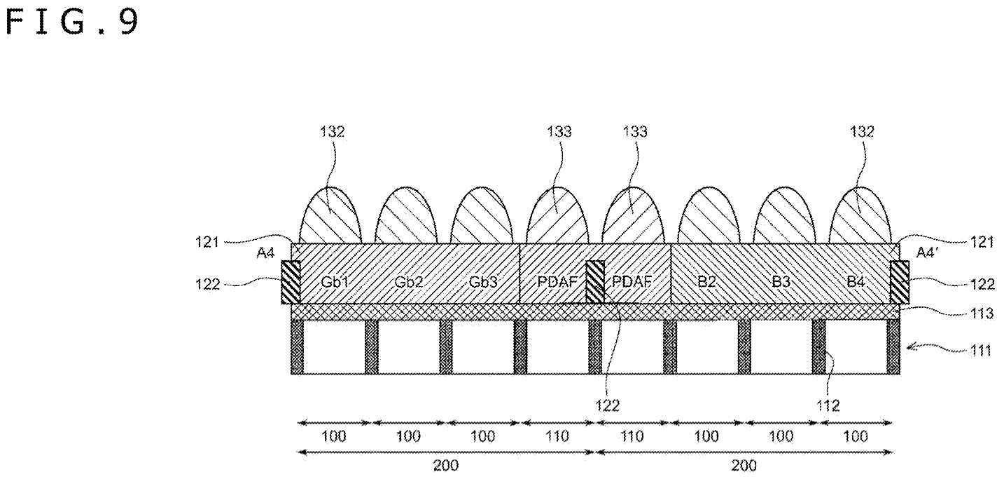

FIG. 8 is a plan view illustrating a fourth example of the structure to which the present disclosure is applied. FIG. 9 is a cross-sectional view illustrating a cross section A4-A4′ in the plane layout of FIG. 8.

As compared to the structure illustrated in the plane layout of FIG. 6, the structure illustrated in the plane layout of FIG. 8 is a structure that further combines the combination of a 4×4-OCL structure and a 1×1-OCL structure with structures of phase difference pixels (PDAF pixels) for acquiring phase difference information.

In FIG. 8, the pixel sections 200 of the corresponding colors, namely, red (R), green (G), and blue (B), are disposed in a Bayer array. In the upper-left and lower-right regions of the four divided regions, in which the single on-chip micro lens 132 is disposed for each pixel forming the pixel sections 200 of the corresponding colors, phase difference pixels 110 used for phase detection auto focus (PDAF) are provided. In FIG. 8, an on-chip micro lens 133 is disposed for every two phase difference pixels 110.

That is, when the region illustrated in the plan view of FIG. 8 is divided into four, the four pixel sections 200 in each of the upper-right and lower-left regions have 4×4-OCL structures. Meanwhile, the four pixel sections 200 in each of the upper-left and lower-right regions have 1×1-OCL structures including the phase difference pixels 110. In the upper-right and lower-left regions, the single on-chip micro lens 141 is disposed in the gap portion that is a region in which the regions of the on-chip micro lenses 131 disposed for the pixel sections 200 of the corresponding colors are absent, thereby forming a 2×2-OCL structure. Meanwhile, in each of the upper-left and lower-right regions, the four pixels in the central part have the structures of the phase difference pixels 110, while the surrounding regions excluding the four pixels in the central part have 1×1-OCL structures.

As illustrated in the cross-sectional view of FIG. 9, in the Gb pixel section, the single on-chip micro lens 132 is disposed for each of the Gb pixels provided with the G color filters 121-Gb1 to Gb3. In the Gb pixel section, for the phase difference pixel 110, the single on-chip micro lens 133 that the phase difference pixel 110 in question shares with the counterpart phase difference pixel is disposed. In the B pixel section, the single on-chip micro lens 132 is disposed for each of the B pixels provided with the B color filters 121-B2 to B4. In the B pixel section, for the phase difference pixel 110, the single on-chip micro lens 133 that the phase difference pixel 110 in question shares with the counterpart phase difference pixel is disposed.

As described above, in the fourth example of the structure, when combined structures of 4×4-OCL structures, 1×1-OCL structures, and PDAF structures are applied to the pixel sections 200 of the corresponding colors disposed in a Bayer array, the 2×2-OCL structure is disposed in the gap portion located in the central part of every four pixel sections 200 with a 4×4-OCL structure, thereby suppressing a reduction in the sensitivity of the pixels 100 located in the gap portions.

Further, in a case where phase difference information is acquired from the pixel sections 200 with a 4×4-OCL structure, even when there is some malfunction and phase difference information cannot be acquired, phase difference information acquired by the phase difference pixels 110 can be used. Further, as with the third example of the structure, with the combination of a 4×4-OCL structure and a 1×1-OCL structure, even when misalignments occur, that is, the on-chip micro lenses are shifted from the intended positions, it is possible to reduce the influence of the difference in sensitivity between same-color pixels.

### Fifth Example of Structure

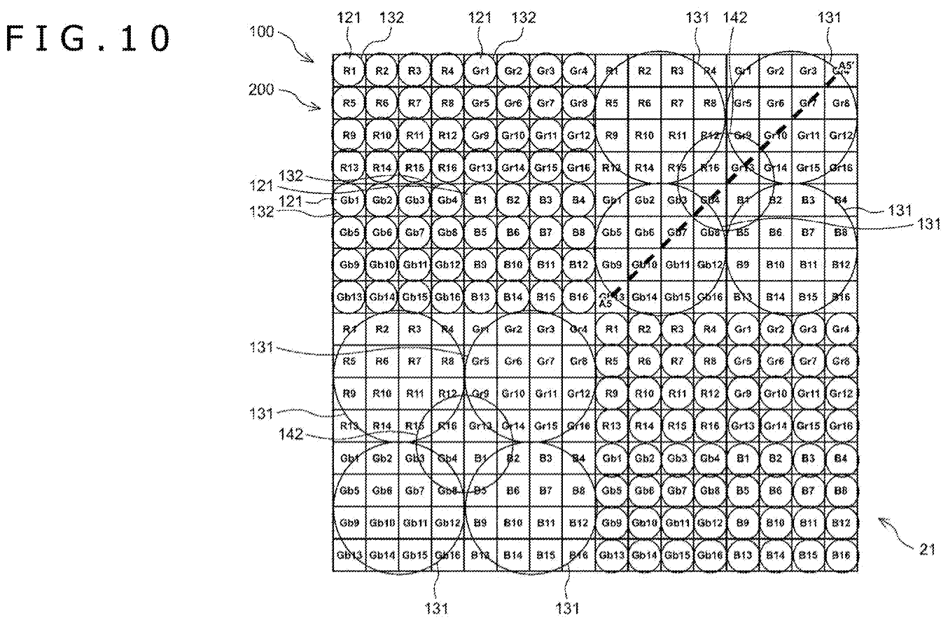

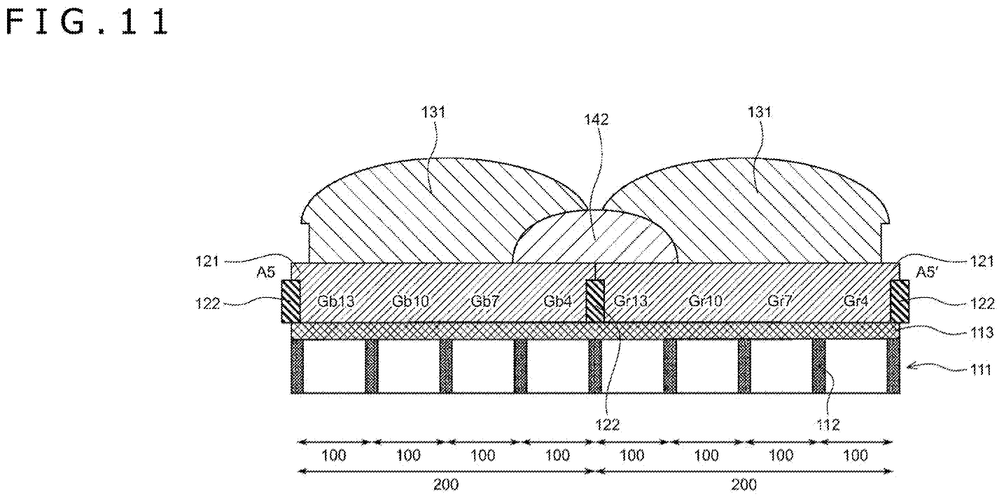

FIG. 10 is a plan view illustrating a fifth example of the structure to which the present disclosure is applied. FIG. 11 is a cross-sectional view illustrating a cross section A5-A5′ in the plane layout of FIG. 10.

In the structure illustrated in the plane layout of FIG. 10, as compared to the structure illustrated in the plane layout of FIG. 6, the inner lenses 142 are disposed in the gap portions due to the 4×4-OCL structures, instead of the on-chip micro lenses 141.

In FIG. 10, among the 4×4-OCL structures and the 1×1-OCL structures, in the 4×4-OCL structures, the single inner lens 142 is disposed in each gap portion near the on-chip micro lens 131 disposed for each of the adjacent four pixel sections 200.

As illustrated in the cross-sectional view of FIG. 11, in each of the Gr pixel section and the Gb pixel section, the single on-chip micro lens 131 is disposed. Further, in the Gr pixel section and the Gb pixel section, the Gr pixel provided with the G color filter 121-Gr13 and the Gb pixel provided with the G color filter 121-Gb4 are partially located in the gap portion, and hence, the inner lens 142 is disposed on the G color filter 121-Gr13 and the G color filter 121-Gb4.

As described above, in the fifth example of the structure, when combined structures of 4×4-OCL structures and 1×1-OCL structures are applied to the pixel sections 200 of the corresponding colors disposed in a Bayer array, the OCL (inner lens) is disposed in the gap portion located in the central part of every four pixel sections 200 with a 4×4-OCL structure, thereby suppressing a reduction in the sensitivity of the pixels 100 located in the gap portions. Further, as with the third example of the structure, with the combination of a 4×4-OCL structure and a 1×1-OCL structure, even when misalignments occur, that is, the on-chip micro lenses are shifted from the intended positions, it is possible to reduce the influence of the difference in sensitivity between same-color pixels.

### Sixth Example of Structure

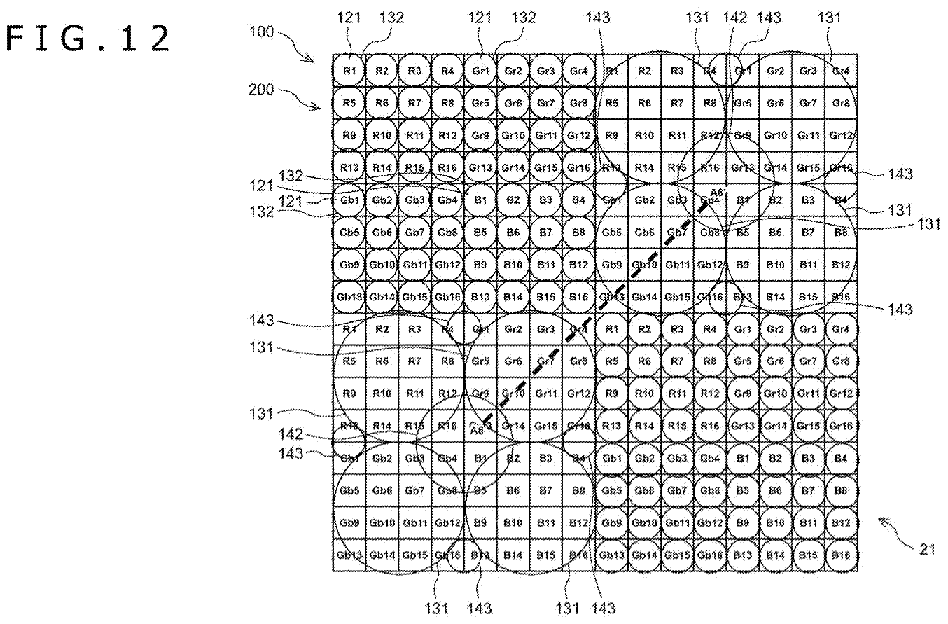

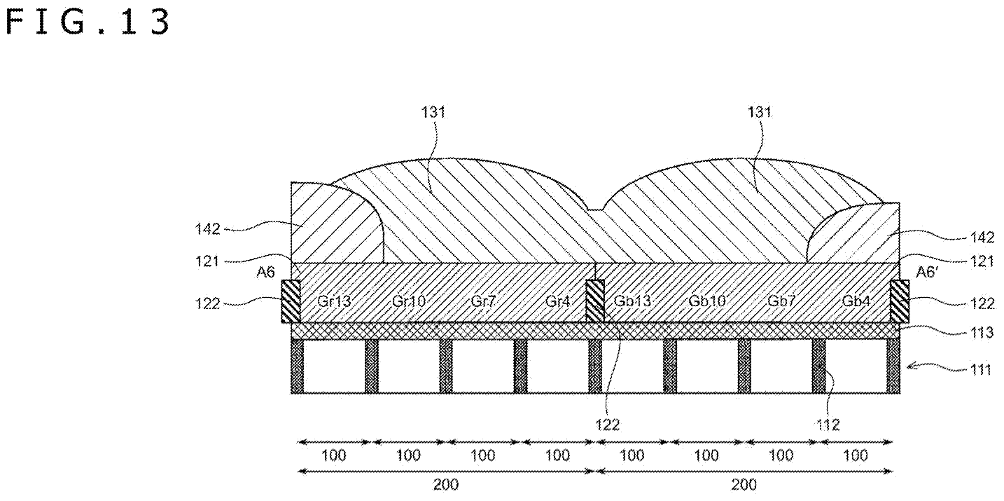

FIG. 12 is a plan view illustrating a sixth example of the structure to which the present disclosure is applied. FIG. 13 is a cross-sectional view illustrating a cross section A6-A6′ in the plane layout of FIG. 12.

In the structure illustrated in the plane layout of FIG. 12, as compared to the structure illustrated in the plane layout of FIG. 10, on-chip micro lenses 143 are further disposed in the gap portions (inter-different-color gap portions) located between the pixel sections 200 (pixels 100 thereof) of different colors.

In FIG. 12, among the 4×4-OCL structures and the 1×1-OCL structures, in the 4×4-OCL structures, the single inner lens 142 is disposed in each gap portion near the on-chip micro lens 131 disposed for each of the adjacent four pixel sections 200. Further, regarding the pixel sections 200 with a 4×4-OCL structure, in an inter-different-color gap portion that is the gap portion located between the pixel sections 200 (pixels 100 thereof) of different colors, the single on-chip micro lens 143 is disposed.

As illustrated in the cross-sectional view of FIG. 13, in each of the Gb pixel section and the Gr pixel section, the single on-chip micro lens 131 is disposed. In the Gb pixel section, the Gb pixel provided with the G color filter 121-Gb4 is partially located in the gap portion, and hence, the inner lens 142 is disposed on the G color filter 121-Gb4. Further, in the Gr pixel section, the Gr pixel provided with the G color filter 121-Gr13 is partially located in the gap portion, and hence, the inner lens 142 is disposed on the G color filter 121-Gr13.

As described above, in the sixth example of the structure, when combined structures of 4×4-OCL structures and 1×1-OCL structures are applied to the pixel sections 200 of the corresponding colors disposed in a Bayer array, the OCL (inner lens) is disposed in the gap portion located in the central part of every four pixel sections 200 with a 4×4-OCL structure, and the OCLs (on-chip micro lenses 143) are disposed in the inter-different-color gap portions, thereby suppressing a reduction in the sensitivity of the pixels 100 located in those gap portions. Further, as with the third example of the structure, with the combination of a 4×4-OCL structure and a 1×1-OCL structure, even when misalignments occur, that is, the on-chip micro lenses are shifted from the intended positions, it is possible to reduce the influence of the difference in sensitivity between same-color pixels.

Note that, in the sixth example of the structure, the structure in which the OCLs (inner lenses) are disposed in the gap portions has been described, but the gap portions in question may be provided with 2×2-OCL structures.

### Seventh Example of Structure

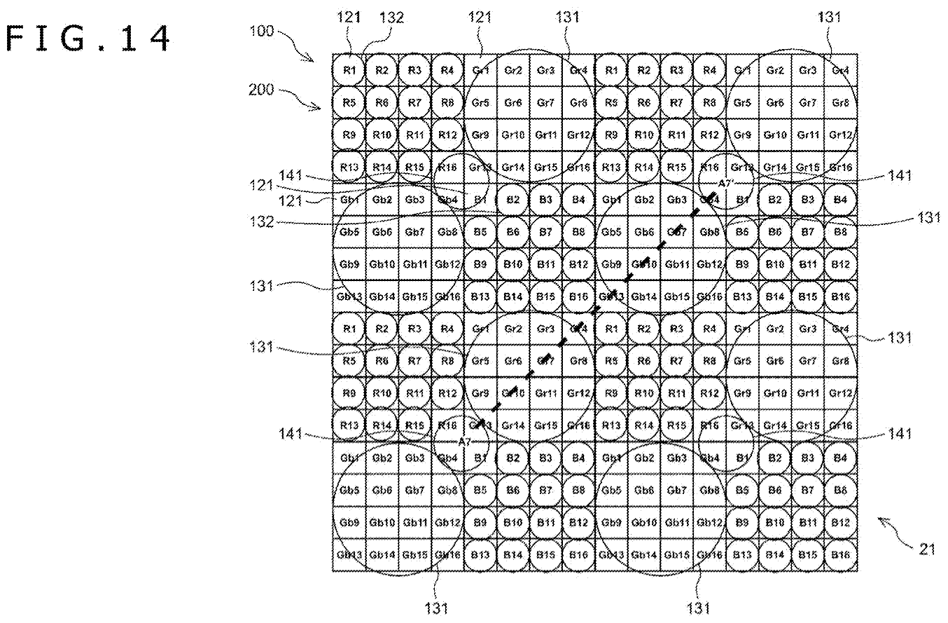

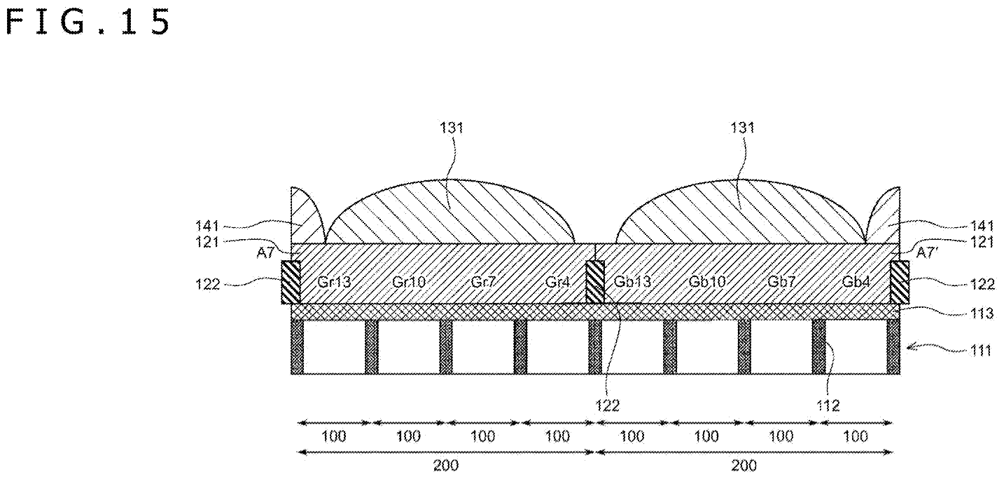

FIG. 14 is a plan view illustrating a seventh example of the structure to which the present disclosure is applied. FIG. 15 is a cross-sectional view illustrating a cross section A7-A7′ in the plane layout of FIG. 14.

The structure illustrated in the plane layout of FIG. 14 is, as with the structure illustrated in the plane layout of FIG. 6, a combined structure of a 4×4-OCL structure and a 1×1-OCL structure in which the gap portions due to the 4×4-OCL structures are provided with 2×2-OCL structures, but is different from the structure of FIG. 6 in that, while the Gr pixel sections and the Gb pixel sections have 4×4-OCL structures, the R pixel sections and the B pixel sections have 1×1-OCL structures.

In FIG. 14, the pixel sections 200 of the corresponding colors, namely, red (R), green (G), and blue (B), are disposed in a Bayer array, and the single on-chip micro lens 131 is disposed for the whole 16 (4×4) pixels forming each of the Gr pixel sections and the Gb pixel sections, while the single on-chip micro lens 132 is disposed for each pixel forming the R pixel sections and the B pixel sections.

Further, when the region illustrated in the plan view of FIG. 14 is divided into four, in each region, the single on-chip micro lens 141 is disposed in the gap portion due to the two on-chip micro lenses 131 disposed for the Gr pixel section and the Gb pixel section, thereby forming a 2×2-OCL structure. To achieve the 2×2-OCL structure, some of the pixels in the R pixel section and the B pixel section do not have a 1×1-OCL structure but have a 2×2-OCL structure. Specifically, in the R pixel section and the B pixel section, the R pixel provided with the R color filter 121-R16 and the B pixel provided with the B color filter 121-B1 have a 2×2-OCL structure.

As illustrated in the cross-sectional view of FIG. 15, in each of the Gb pixel section and the Gr pixel section, the single on-chip micro lens 131 is disposed. Further, in the Gb pixel section and the Gr pixel section, the Gb pixel provided with the G color filter 121-Gb4 and the Gr pixel provided with the G color filter 121-Gr13 are partially located in the gap portions, and hence, the on-chip micro lenses 141 are disposed on the G color filter 121-Gb4 and the G color filter 121-Gr13.

As described above, in the seventh example of the structure, when 4×4-OCL structures are applied to the Gr pixel sections and the Gb pixel sections disposed in a Bayer array, while 1×1-OCL structures are applied to the R pixel sections and the B pixel sections, the 2×2-OCL structures are disposed in the gap portions due to the 4×4-OCL structures, thereby suppressing a reduction in the sensitivity of the pixels 100 located in the gap portions. Further, by applying 4×4-OCL structures to the Gr pixel sections and the Gb pixel sections, it is possible to enhance the sensitivity of the Gr pixels and the Gb pixels. By using at least either the Gr pixel sections or the Gb pixel sections, which have 4×4-OCL structures, as phase difference pixel sections, it is possible to acquire phase difference information from the phase difference pixel sections in question.

Note that, in the seventh example of the structure, the structure in which all the Gr pixel sections and Gb pixel sections have 4×4-OCL structures has been described, but some of the Gr pixel sections and the Gb pixel sections may have 4×4-OCL structures and the remaining Gr pixel sections and Gb pixel sections may have 1×1-OCL structures.

### Eighth Example of Structure

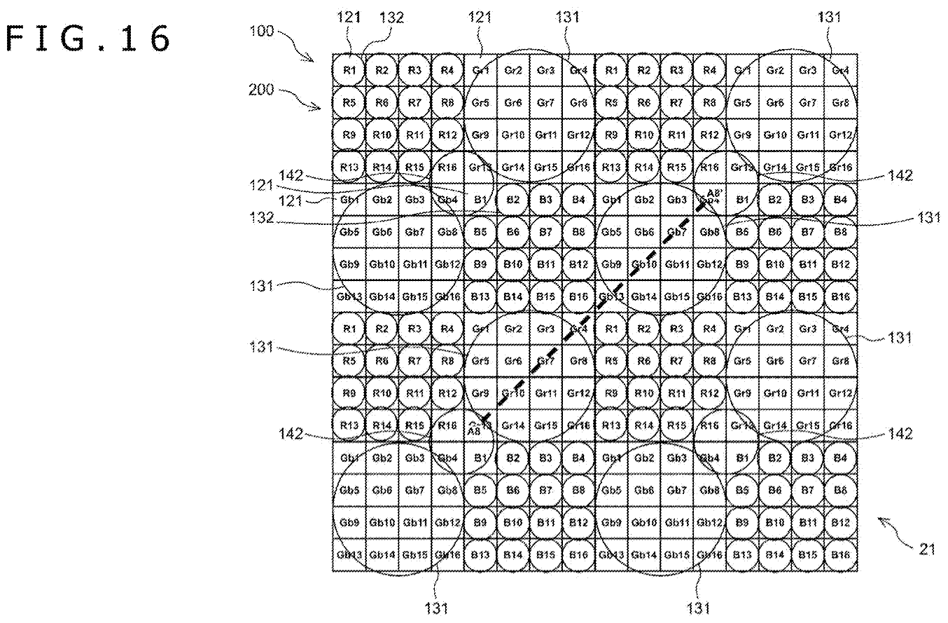

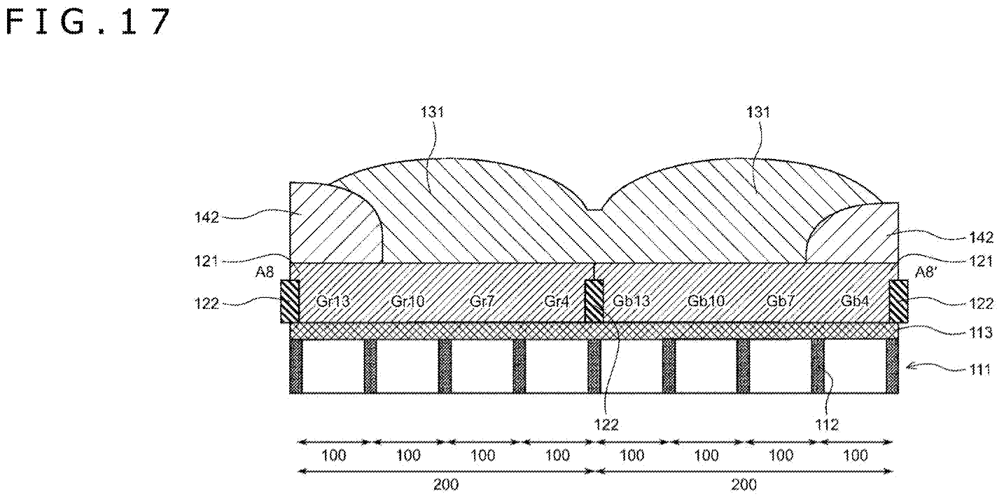

FIG. 16 is a plan view illustrating an eighth example of the structure to which the present disclosure is applied. FIG. 17 is a cross-sectional view illustrating a cross section A8-A8′ in the plane layout of FIG. 16.

In the structure illustrated in the plane layout of FIG. 16, as compared to the structure illustrated in the plane layout of FIG. 14, the inner lenses 142 are disposed instead of the on-chip micro lenses 141.

In FIG. 16, the single inner lens 142 is disposed in each gap portion near the on-chip micro lens 131 disposed for each of the Gr pixel sections and the Gb pixel sections.

As illustrated in the cross-sectional view of FIG. 17, in each of the Gb pixel section and the Gr pixel section, the single on-chip micro lens 131 is disposed. In the Gb pixel section and the Gr pixel section, the Gb pixel provided with the G color filter 121-Gb4 and the Gr pixel provided with the G color filter 121-Gr13 are partially located in the gap portions, and hence, the inner lenses 142 are disposed on the G color filter 121-Gb4 and the G color filter 121-Gr13.

As described above, in the eighth example of the structure, when 4×4-OCL structures are applied to the Gr pixel sections and the Gb pixel sections disposed in a Bayer array, while 1×1-OCL structures are applied to the R pixel sections and the B pixel sections, the OCLs (inner lenses) are disposed in the gap portions due to the 4×4-OCL structures, thereby suppressing a reduction in the sensitivity of the pixels 100 located in the gap portions. Further, by applying 4×4-OCL structures to the Gr pixel sections and the Gb pixel sections, it is possible to enhance the sensitivity of the Gr pixels and the Gb pixels. By using at least either the Gr pixel sections or the Gb pixel sections, which have 4×4-OCL structures, as phase difference pixel sections, it is possible to acquire phase difference information from the phase difference pixel sections in question.

Note that, in the eighth example of the structure, the structure in which all the Gr pixel sections and Gb pixel sections have 4×4-OCL structures has been described, but some of the Gr pixel sections and the Gb pixel sections may have 4×4-OCL structures and the remaining Gr pixel sections and Gb pixel sections may have 1×1-OCL structures.

### Ninth Example of Structure

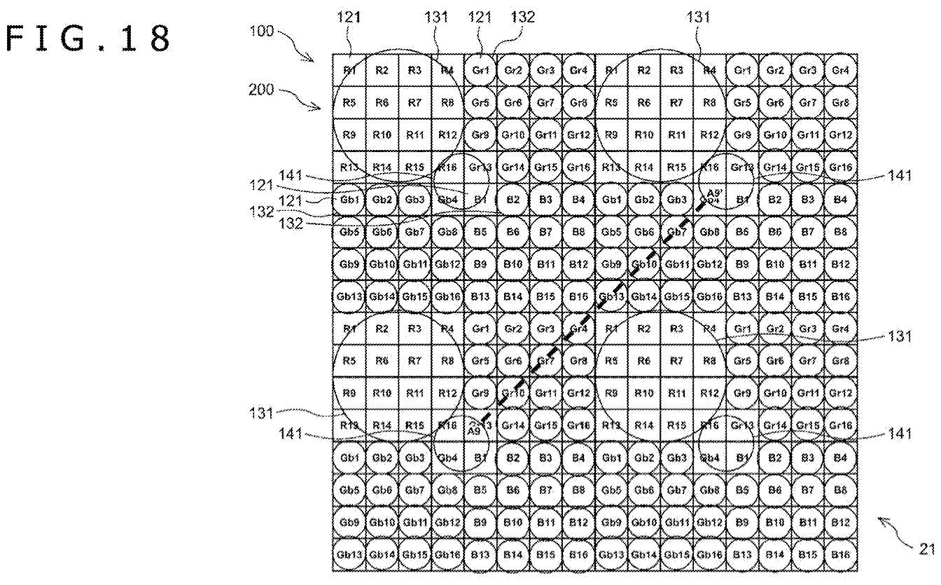

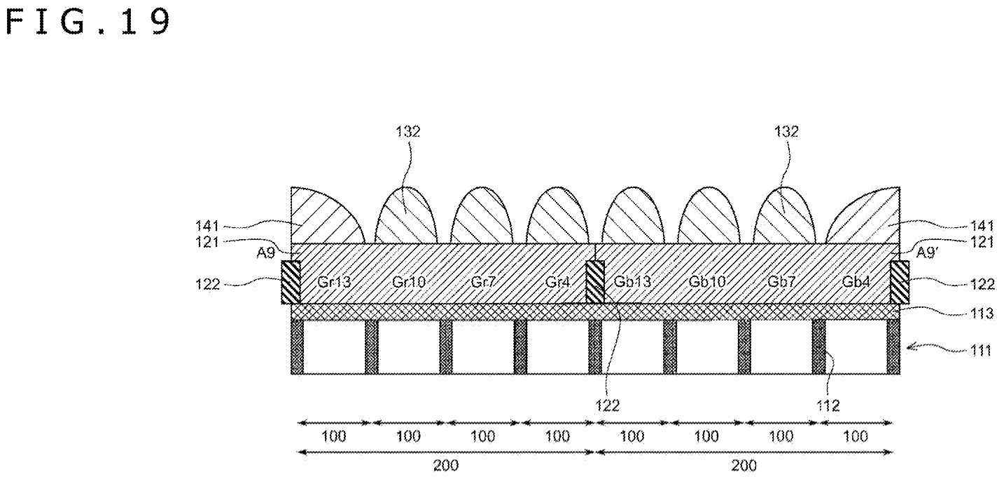

FIG. 18 is a plan view illustrating a ninth example of the structure to which the present disclosure is applied. FIG. 19 is a cross-sectional view illustrating a cross section A9-A9′ in the plane layout of FIG. 18.

The structure illustrated in the plane layout of FIG. 18 is, as with the structure illustrated in the plane layout of FIG. 6, a combined structure of a 4×4-OCL structure and a 1×1-OCL structure in which the gap portions due to the 4×4-OCL structures are provided with 2×2-OCL structures, but is different from the structure of FIG. 6 in that, while the R pixel sections have 4×4-OCL structures, the G pixel sections and the B pixel sections have 1×1-OCL structures.

In FIG. 18, the pixel sections 200 of the corresponding colors, namely, red (R), green (G), and blue (B), are disposed in a Bayer array, and the single on-chip micro lens 131 is disposed for the whole 16 (4×4) pixels forming each R pixel section, while the single on-chip micro lens 132 is disposed for each pixel forming the Gr pixel sections, the Gb pixel sections, and the B pixel sections.

Further, when the region illustrated in the plan view of FIG. 18 is divided into four, in each region, the single on-chip micro lens 141 is disposed in the gap portion due to the single on-chip micro lens 131 disposed for the R pixel section, thereby forming a 2×2-OCL structure. To achieve the 2×2-OCL structure, some of the pixels in the Gr pixel section, the Gb pixel section, and the B pixel section do not have a 1×1-OCL structure but have a 2×2-OCL structure. Specifically, in the Gr pixel section, the Gb pixel section, and the B pixel section, the Gr pixel and the Gb pixel provided with the G color filters 121-Gr13 and Gb4 and the B pixel provided with the B color filter 121-B1 have a 2×2-OCL structure.

As illustrated in the cross-sectional view of FIG. 19, in the Gb pixel section, the single on-chip micro lens 132 is disposed for each Gb pixel provided with the G color filter 121-Gb7, Gb10, or Gb13. The Gb pixel provided with the G color filter 121-Gb4 has a 2×2-OCL structure, and hence, the on-chip micro lens 141 is disposed for the pixel in question. In the Gr pixel section, the single on-chip micro lens 132 is disposed for each Gr pixel provided with the G color filter 121-Gr4, Gr7, or Gr10. The Gr pixel provided with the G color filter 121-Gr13 has a 2×2-OCL structure, and hence, the on-chip micro lens 141 is disposed for the pixel in question.

As described above, in the ninth example of the structure, when 4×4-OCL structures are applied to the R pixel sections disposed in a Bayer array, while 1×1-OCL structures are applied to the G pixel sections and the B pixel sections, the 2×2-OCL structures are disposed in the gap portions due to the 4×4-OCL structures, thereby suppressing a reduction in the sensitivity of the pixels 100 located in the gap portions. Further, by applying 4×4-OCL structures to the R pixel sections, it is possible to enhance the sensitivity of the R pixels. By using the R pixel sections, which have 4×4-OCL structures, as phase difference pixel sections, it is possible to acquire phase difference information.

Note that, in the ninth example of the structure, the structure in which all the R pixel sections have 4×4-OCL structures has been described, but some of the R pixel sections may have 4×4-OCL structures and the remaining R pixel sections may have 1×1-OCL structures.

### Tenth Example of Structure

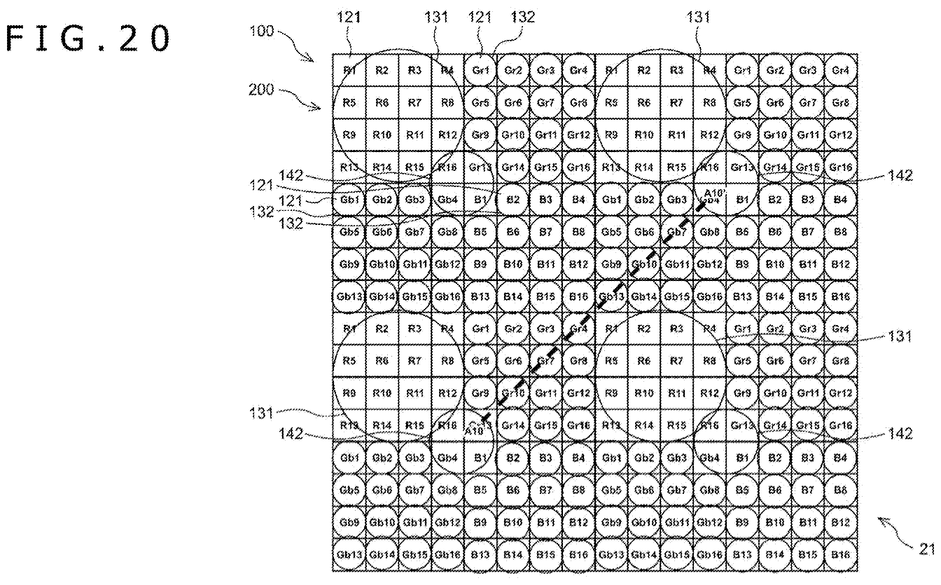

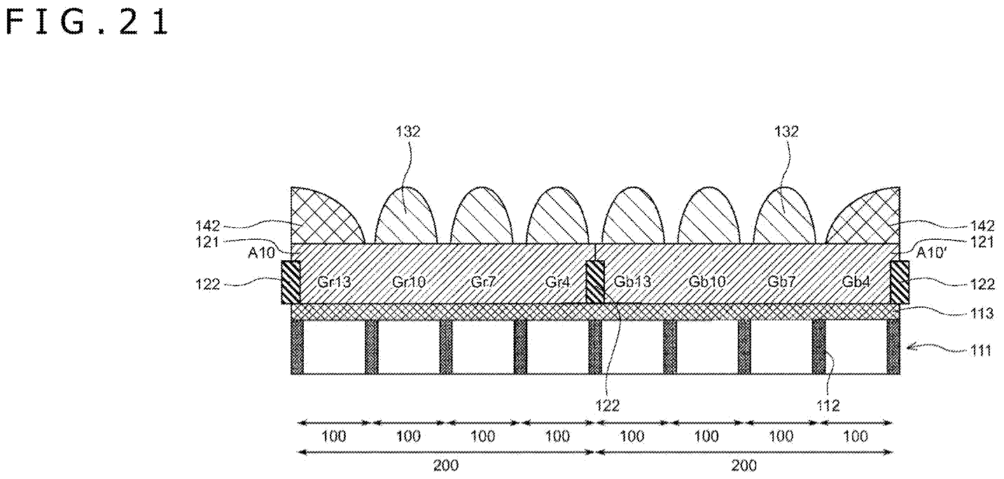

FIG. 20 is a plan view illustrating a tenth example of the structure to which the present disclosure is applied. FIG. 21 is a cross-sectional view illustrating a cross section A10-A10′ in the plane layout of FIG. 20.

In the structure illustrated in the plane layout of FIG. 20, as compared to the structure illustrated in the plane layout of FIG. 18, the inner lenses 142 are disposed instead of the on-chip micro lenses 141.

In FIG. 20, the single inner lens 142 is disposed in each gap portion near the single on-chip micro lens 131 disposed for each R pixel section.

As illustrated in the cross-sectional view of FIG. 21, in the Gb pixel section and the Gr pixel section, the single on-chip micro lens 132 is disposed for each of the Gb pixels and the Gr pixels provided with the G color filters 121. However, the inner lenses 142 are disposed for the Gb pixel provided with the G color filter 121-Gb4 and the Gr pixel provided with the G color filter 121-Gr13.

As described above, in the tenth example of the structure, when 4×4-OCL structures are applied to the R pixel sections disposed in a Bayer array, while 1×1-OCL structures are applied to the G pixel sections and the B pixel sections, the OCLs (inner lenses) are disposed in the gap portions due to the 4×4-OCL structures, thereby suppressing a reduction in the sensitivity of the pixels 100 located in the gap portions. Further, by applying 4×4-OCL structures to the R pixel sections, it is possible to enhance the sensitivity of the R pixels. By using the R pixel sections, which have 4×4-OCL structures, as phase difference pixel sections, it is possible to acquire phase difference information.

Note that, in the tenth example of the structure, the structure in which all the R pixel sections have 4×4-OCL structures has been described, but some of the R pixel sections may have 4×4-OCL structures and the remaining R pixel sections may have 1×1-OCL structures.

### Eleventh Example of Structure

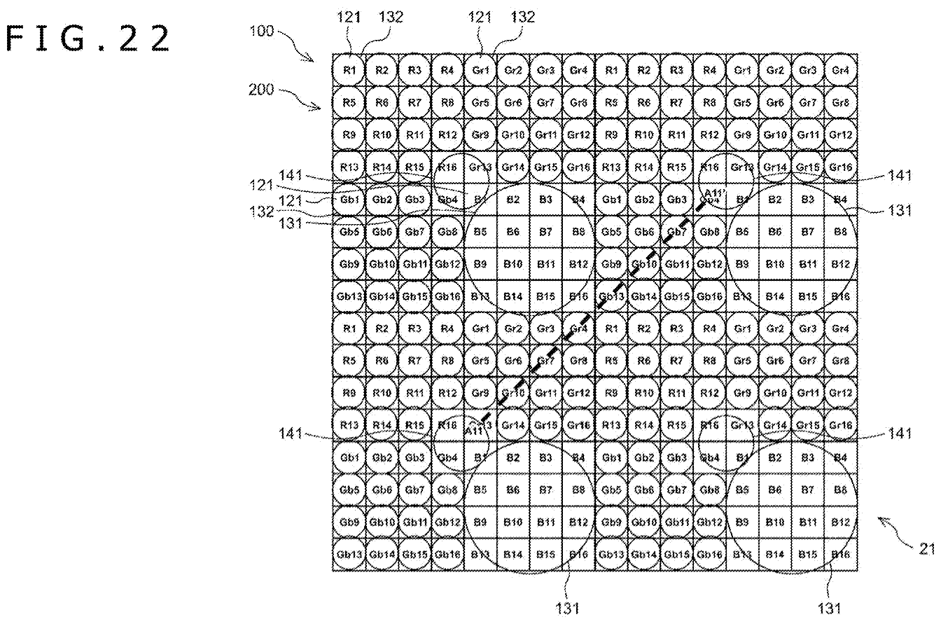

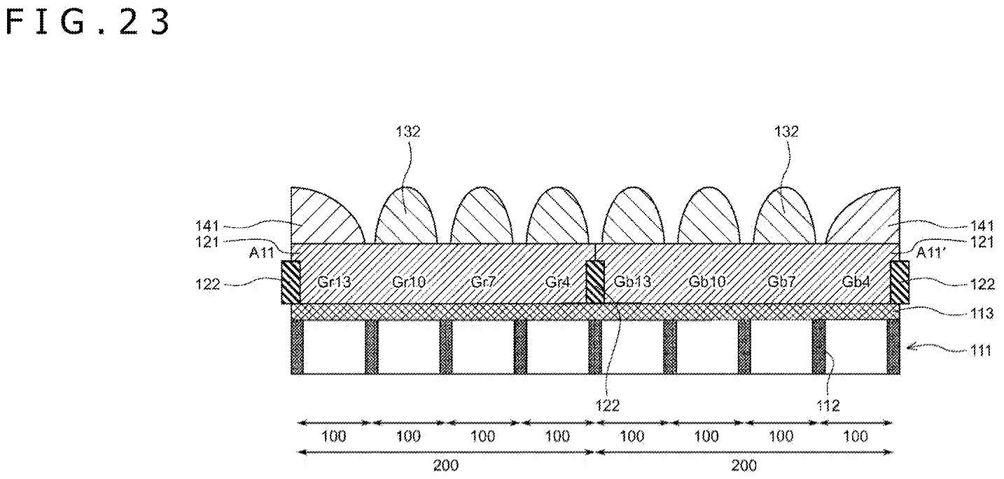

FIG. 22 is a plan view illustrating an eleventh example of the structure to which the present disclosure is applied. FIG. 23 is a cross-sectional view illustrating a cross section A11-A11′ in the plane layout of FIG. 22.

The structure illustrated in the plane layout of FIG. 22 is, as with the structure illustrated in the plane layout of FIG. 6, a combined structure of a 4×4-OCL structure and a 1×1-OCL structure in which the gap portions due to the 4×4-OCL structures are provided with 2×2-OCL structures, but is different from the structure of FIG. 6 in that, while the B pixel sections have 4×4-OCL structures, the R pixel sections and the G pixel sections have 1×1-OCL structures.

In FIG. 22, the pixel sections 200 of the corresponding colors, namely, red (R), green (G), and blue (B), are disposed in a Bayer array, and the single on-chip micro lens 131 is disposed for the whole 16 (4×4) pixels forming each B pixel section, while the single on-chip micro lens 132 is disposed for each pixel forming the R pixel sections, the Gr pixel sections, and the Gb pixel sections.

Further, when the region illustrated in the plan view of FIG. 22 is divided into four, in each region, the single on-chip micro lens 141 is disposed in the gap portion due to the single on-chip micro lens 131 disposed for the B pixel section, thereby forming a 2×2-OCL structure. To achieve the 2×2-OCL structure, some of the pixels in the R pixel section, the Gr pixel section, and the Gb pixel section do not have a 1×1-OCL structure but have a 2×2-OCL structure. Specifically, in the R pixel section, the Gr pixel section, and the Gb pixel section, the R pixel provided with the R color filter 121-R16 and the Gr pixel and the Gb pixel provided with the G color filters 121-Gr13 and Gb4 have a 2×2-OCL structure.

As illustrated in the cross-sectional view of FIG. 23, in the Gb pixel section and the Gr pixel section, the single on-chip micro lens 132 is disposed for each of the Gb pixels and the Gr pixels provided with the G color filters 121. However, the Gb pixel provided with the G color filter 121-Gb4 and the Gr pixel provided with the G color filter 121-Gr13 have 2×2-OCL structures, and hence, the on-chip micro lenses 141 are disposed for the pixels in question.

As described above, in the eleventh example of the structure, when 4×4-OCL structures are applied to the B pixel sections disposed in a Bayer array, while 1×1-OCL structures are applied to the R pixel sections and the G pixel sections, the 2×2-OCL structures are disposed in the gap portions due to the 4×4-OCL structures, thereby suppressing a reduction in the sensitivity of the pixels 100 located in the gap portions. Further, by applying 4×4-OCL structures to the B pixel sections, it is possible to enhance the sensitivity of the B pixels. By using the B pixel sections, which have 4×4-OCL structures, as phase difference pixel sections, it is possible to acquire phase difference information.

Note that, in the eleventh example of the structure, the structure in which all the B pixel sections have 4×4-OCL structures has been described, but some of the B pixel sections may have 4×4-OCL structures and the remaining B pixel sections may have 1×1-OCL structures.

### Twelfth Example of Structure

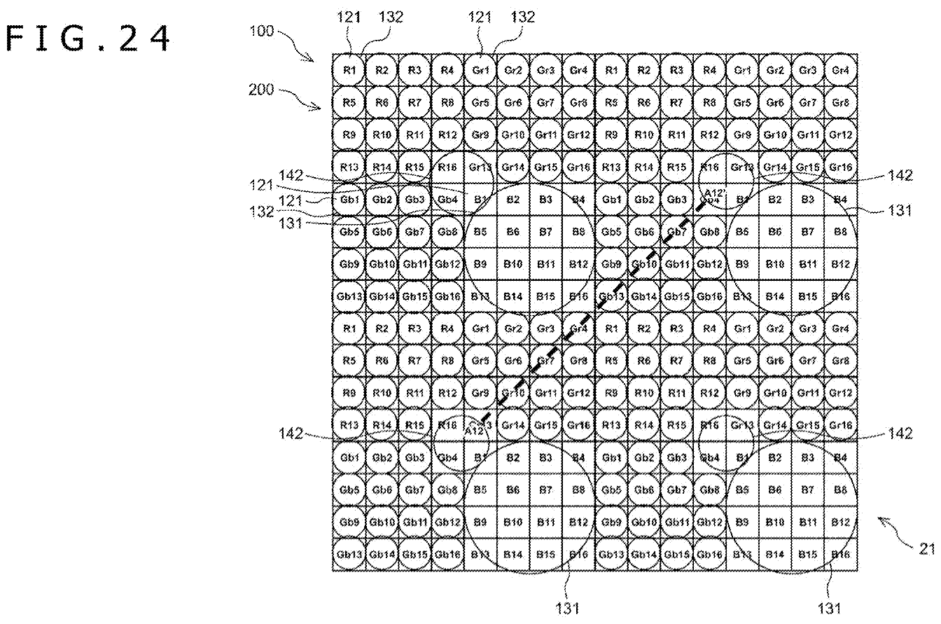

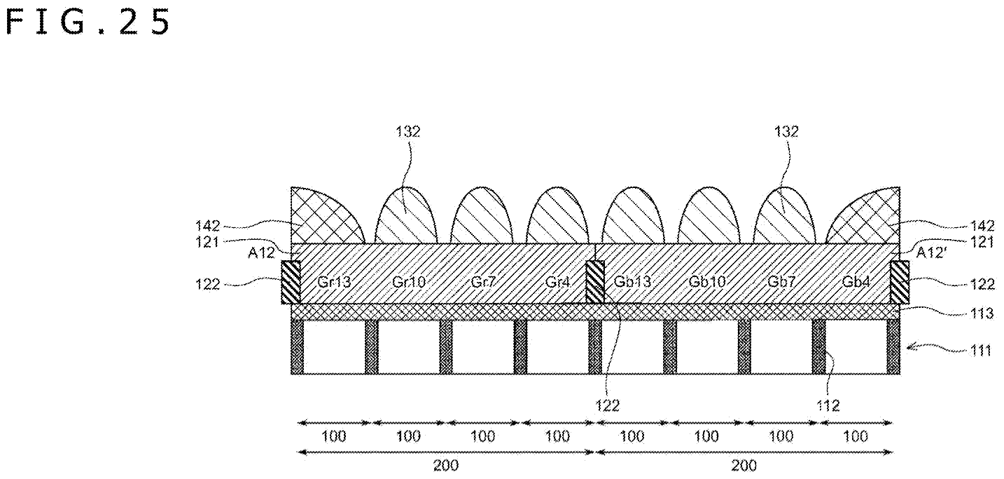

FIG. 24 is a plan view illustrating a twelfth example of the structure to which the present disclosure is applied. FIG. 25 is a cross-sectional view illustrating a cross section A12-A12′ in the plane layout of FIG. 24.

In the structure illustrated in the plane layout of FIG. 24, as compared to the structure illustrated in the plane layout of FIG. 22, the inner lenses 142 are disposed instead of the on-chip micro lenses 141.

In FIG. 24, the single inner lens 142 is disposed in each gap portion near the single on-chip micro lens 131 disposed for each B pixel section.

As illustrated in the cross-sectional view of FIG. 25, in the Gb pixel section and the Gr pixel section, the single on-chip micro lens 132 is disposed for each of the Gb pixels and the Gr pixels provided with the G color filters 121. However, the inner lenses 142 are disposed for the Gb pixel provided with the G color filter 121-Gb4 and the Gr pixel provided with the G color filter 121-Gr13.

As described above, in the twelfth example of the structure, when 4×4-OCL structures are applied to the B pixel sections disposed in a Bayer array, while 1×1-OCL structures are applied to the R pixel sections and the G pixel sections, the OCLs (inner lenses) are disposed in the gap portions due to the 4×4-OCL structures, thereby suppressing a reduction in the sensitivity of the pixels 100 located in the gap portions. Further, by applying 4×4-OCL structures to the B pixel sections, it is possible to enhance the sensitivity of the B pixels. By using the B pixel sections, which have 4×4-OCL structures, as phase difference pixel sections, it is possible to acquire phase difference information.

Note that, in the twelfth example of the structure, the structure in which all the B pixel sections have 4×4-OCL structures has been described, but some of the B pixel sections may have 4×4-OCL structures and the remaining B pixel sections may have 1×1-OCL structures.

### Thirteenth Example of Structure

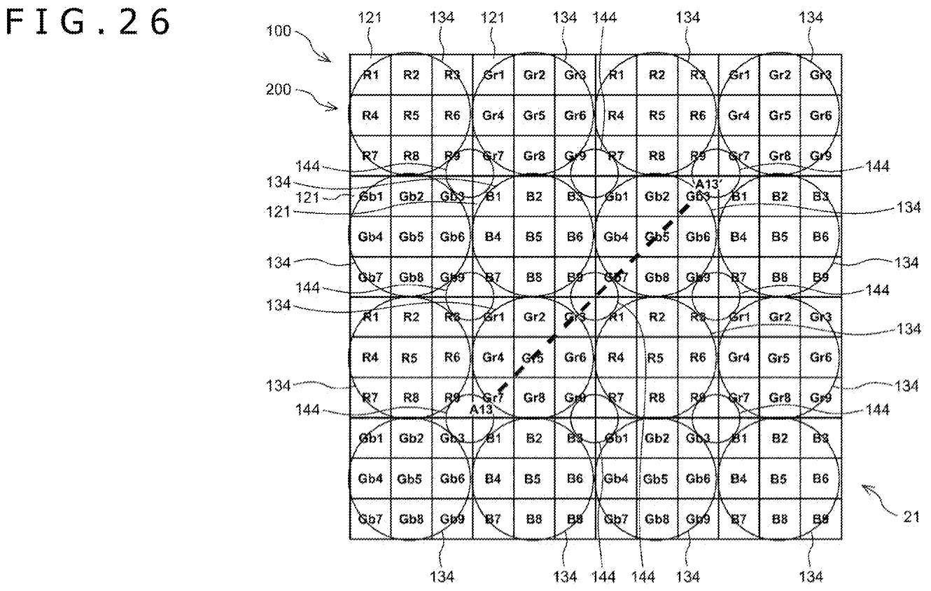

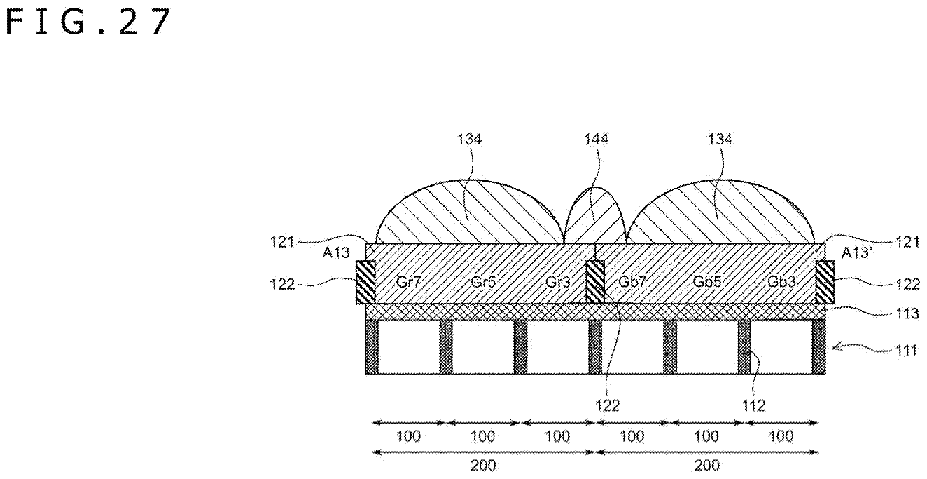

FIG. 26 is a plan view illustrating a thirteenth example of the structure to which the present disclosure is applied. FIG. 27 is a cross-sectional view illustrating a cross section A13-A13′ in the plane layout of FIG. 26.

In the structure illustrated in the plane layout of FIG. 26, as compared to the structure illustrated in the plane layout of FIG. 2, the pixel sections 200 of the corresponding colors have 3×3-OCL structures instead of the 4×4-OCL structures.

In FIG. 26, the pixel sections 200 of the corresponding colors, namely, red (R), green (G), and blue (B), are disposed in a Bayer array, and a single on-chip micro lens 134 is disposed for the whole nine (3×3) pixels forming each pixel section 200 of the corresponding color.

Specifically, the single on-chip micro lens 134 is disposed for the 3×3 R pixels forming each R pixel section. Similarly, with regard to the Gr pixel sections, the Gb pixel sections, and the B pixel sections, the single on-chip micro lens 134 is disposed for the nine (3×3) pixels forming the pixel section 200 of the corresponding color. In the first embodiment, the structure in which the single on-chip micro lens 134 is shared by the 3×3 pixels 100 (color filters 121 thereof) is also referred to as a “3×3-OCL structure.”

In FIG. 26, a single on-chip micro lens 144 is disposed in each gap portion near the four on-chip micro lenses 134. This can suppress a reduction in the sensitivity of the pixels 100 in the gap portions.

As illustrated in the cross-sectional view of FIG. 27, in each of the Gb pixel section and the Gr pixel section, the single on-chip micro lens 134 is disposed. Further, in the Gb pixel section and the Gr pixel section, the Gb pixel provided with the G color filter 121-Gb7 and the Gr pixel provided with the G color filter 121-Gr3 are partially located in the gap portion, and hence, the on-chip micro lens 144 is disposed on the G color filter 121-Gb7 and the G color filter 121-Gr3.

In this way, although the Gb pixel section and the Gr pixel section have 3×3-OCL structures, since the Gb pixel provided with the G color filter 121-Gb7 and the Gr pixel provided with the G color filter 121-Gr3 are located in the gap portion, those G pixels have a 2×2-OCL structure.

As described above, in the thirteenth example of the structure, when 3×3-OCL structures are disposed for the pixel sections 200 of the corresponding colors disposed in a Bayer array, the 2×2-OCL structure is disposed in the gap portion located in the central part of every four pixel sections 200, thereby suppressing a reduction in the sensitivity of the pixels 100 located in the gap portions.

In the above description, as the structure of the pixel sections 200 of the corresponding colors, the 3×3-OCL structures and the 4×4-OCL structures have been exemplified, but the present disclosure can be applied to the pixel section 200 with an n×n-OCL structure (n is an integer of 2 or more), that is, the pixel section 200 including n×n pixels corresponding to color filters of the same color in an n×n array. In the present disclosure, at least some of the pixel sections 200 of the corresponding colors arranged in a predetermined array pattern can have n×n-OCL structures that are structures in which a single on-chip micro lens is shared by n×n pixels, and other on-chip micro lenses can be disposed in the gap portions near the on-chip micro lenses for the n×n-OCL structures.

### Fourteenth Example of Structure

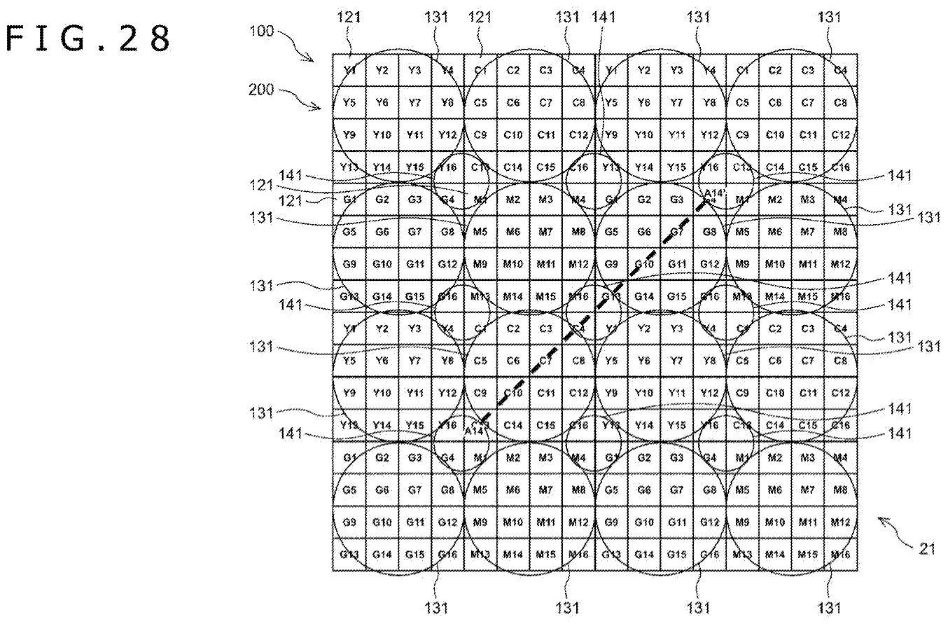

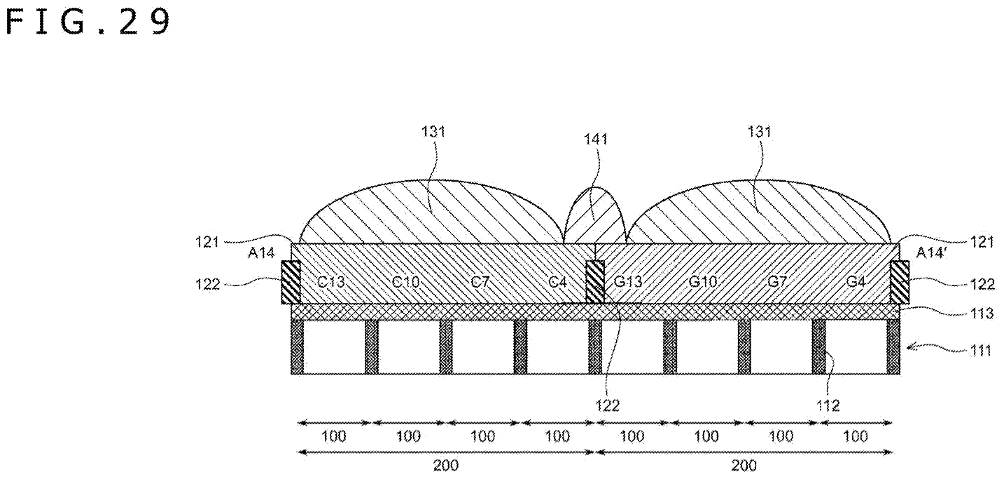

FIG. 28 is a plan view illustrating a fourteenth example of the structure to which the present disclosure is applied. FIG. 29 is a cross-sectional view illustrating a cross section A14-A14′ in the plane layout of FIG. 28.

As compared to the structure illustrated in the plan view of FIG. 2, the structure illustrated in the plan view of FIG. 28 is a structure that uses color filters 121 corresponding to cyan (C), magenta (M), and yellow (Y).

In FIG. 28, for the sake of description, identification information that combines abbreviations representing the colors of the color filters 121, namely, “Y,” “C,” “G,” and “M,” with numbers for identifying each region is described in regions corresponding to the color filters 121 disposed for the pixels 100. Also in FIG. 29, the identification information that combines the abbreviations representing the colors with the numbers is described in regions corresponding to the color filters 121.

Sixteen (4×4) pixels provided with Y color filters 121-Y1 to Y16 configured to transmit a wavelength corresponding to yellow (Y) are configured as Y pixels. The 4×4 Y pixels form a Y pixel section. Sixteen (4×4) pixels provided with C color filters 121-C1 to C16 configured to transmit a wavelength corresponding to cyan (C) are configured as C pixels. The 4×4 C pixels form a C pixel section.

Sixteen (4×4) pixels provided with G color filters 121-G1 to G16 corresponding to green (G) are formed as G pixels. The 4×4 G pixels form a G pixel section. Sixteen (4×4) pixels provided with M color filters 121-M1 to M16 configured to transmit a wavelength corresponding to magenta (M) are configured as M pixels. The 4×4 M pixels form an M pixel section.

In the pixel sections 200 of the corresponding colors, namely, the Y pixel sections, the C pixel sections, the G pixel sections, and the M pixel sections, the single on-chip micro lens 131 is disposed for the 16 (4×4) pixels, thereby forming a 4×4-OCL structure. In FIG. 28, the single on-chip micro lens 141 is disposed in each gap portion near the four on-chip micro lenses 131. This can suppress a reduction in the sensitivity of the pixels 100 in the gap portions.

As illustrated in the cross-sectional view of FIG. 29, in each of the G pixel section and the C pixel section, the single on-chip micro lens 131 is disposed. Further, in the G pixel section and the C pixel section, the G pixel provided with the G color filter 121-G13 and the C pixel provided with the C color filter 121-C4 are partially located in the gap portion, and hence, the on-chip micro lens 141 is disposed on the G color filter 121-G13 and the C color filter 121-C4.

As described above, also in the structure using the color filters corresponding to cyan (C), magenta (M), and yellow (Y) as the color filters 121, instead of color filters corresponding to red (R), green (G), and blue (B), by disposing the 2×2-OCL structures in the gap portions near the on-chip micro lenses 141 for the 4×4-OCL structures, it is possible to suppress a reduction in the sensitivity of the pixels 100 located in the gap portions. Note that the C pixel sections, the M pixel sections, and the Y pixel sections are examples of the pixel sections 200 of colors other than RGB, and the pixel sections 200 of another color, such as structures using W pixel sections including W pixels corresponding to white (W), for example, may be employed.

### Example of Manufacturing Method

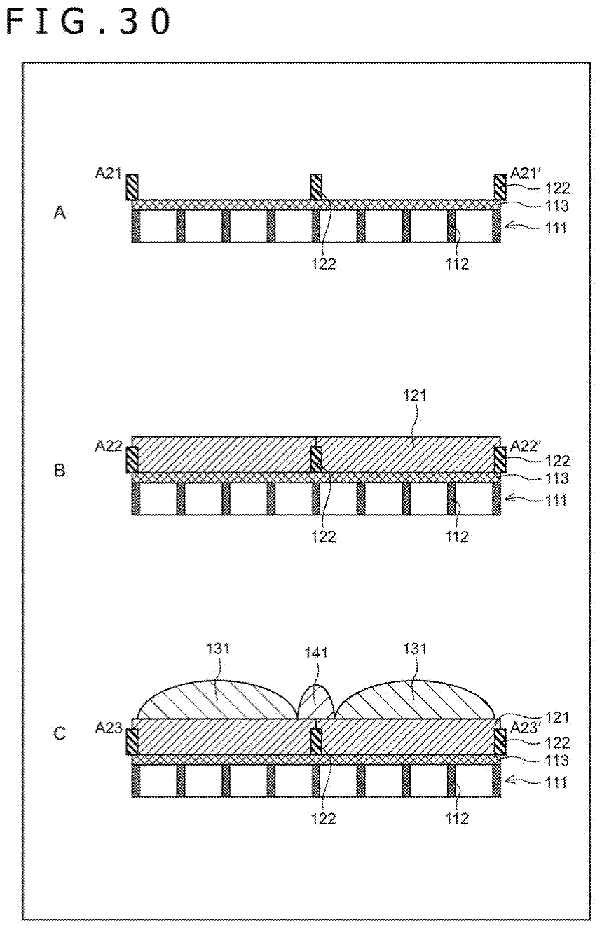

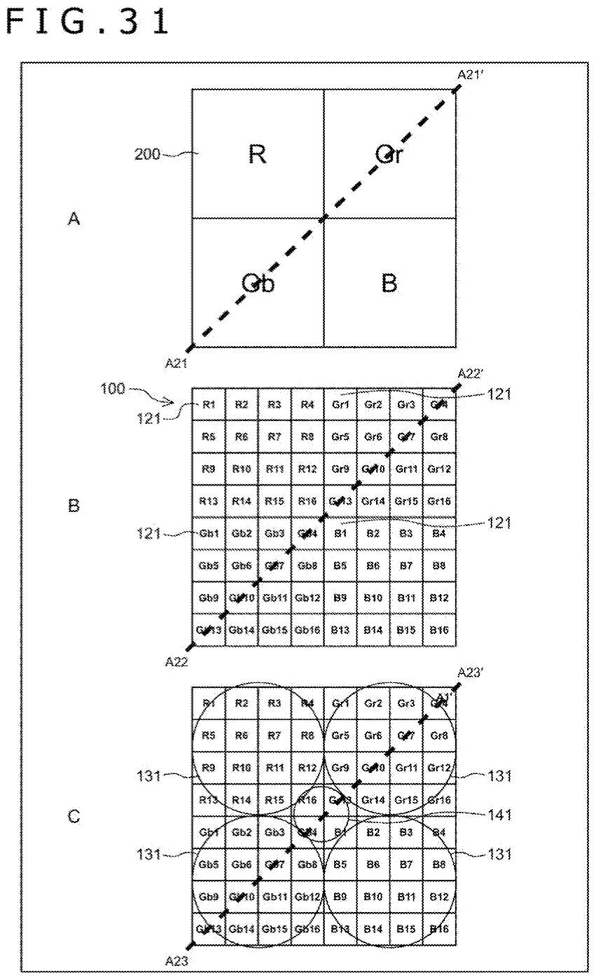

Now, an example of a manufacturing method including steps for forming the structure to which the present disclosure is applied is described with reference to FIG. 30 and FIG. 31. A to C of FIG. 30 illustrate cross-sectional structures corresponding to dashed lines on the plane layouts of A to C of FIG. 31. In this example of the manufacturing method, steps after forming the pixel separation sections 112 and the anti-reflection film 113 on the silicon substrate 111 having formed therein the photoelectric conversion regions are described in the order of the steps.

In the step illustrated in A of FIG. 30, the CF separation sections 122 including a light-shielding material or the like are formed on the anti-reflection film 113. In the step illustrated in B of FIG. 30, the color filters 121 of the corresponding colors are formed. In the step illustrated in C of FIG. 30, the on-chip micro lenses 131 are formed for the pixel sections 200 with 4×4-OCL structures, and the on-chip micro lenses 141 are formed in the gap portions near the on-chip micro lenses 131. By going through such steps, it is possible to form the structure illustrated in FIG. 2 and FIG. 3, for example.

### 2. Second Embodiment

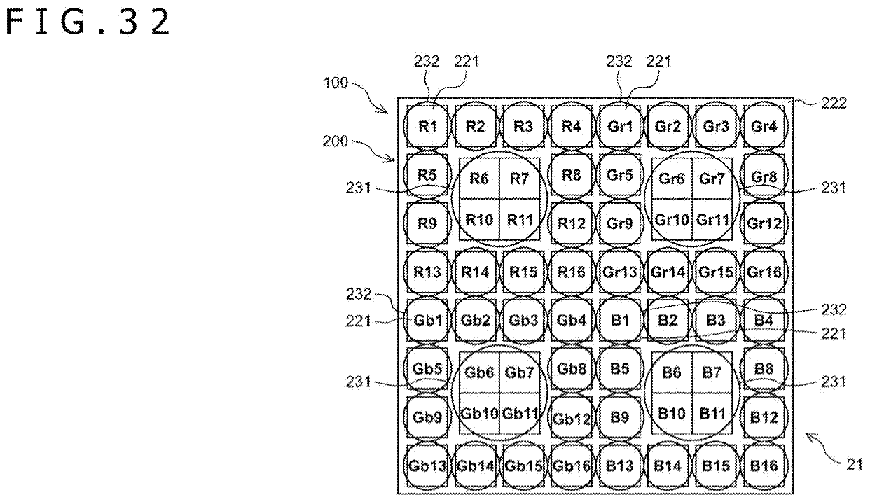

Next, with reference to FIG. 32 to FIG. 55, another example (second embodiment) of the structure including the pixels 100 arranged in a two-dimensional manner in the pixel array section 21 in the solid-state image pickup device 10 is described.

### First Example of Structure

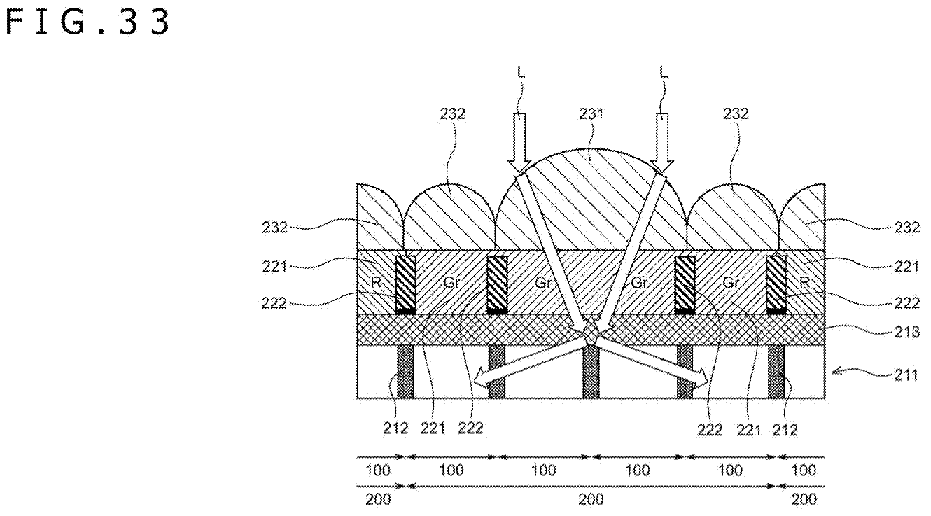

FIG. 32 is a plan view illustrating a first example of a structure to which the present disclosure is applied. FIG. 33 is a cross-sectional view illustrating a cross section including R pixel sections and Gr pixel sections in the plane layout of FIG. 32.

In FIG. 32, each of squares disposed in the row and column directions represents the pixel 100, and for each of the pixels 100, a color filter 221 corresponding to red (R), green (G), or blue (B) is disposed.

In FIG. 32, for the sake of description, identification information that combines abbreviations representing the colors of the color filters 221, namely, “R,” “Gr,” “Gb,” and “B,” with numbers for identifying each region is described in regions corresponding to the color filters 221 disposed for the pixels 100. Also in FIG. 33, the abbreviations representing the colors are described in regions corresponding to the color filters 121.

Sixteen (4×4) pixels provided with R color filters 221-R1 to R16 configured to transmit a wavelength corresponding to red (R) are configured as R pixels. Sixteen (4×4) pixels provided with G color filters 221-Gr1 to Gr16 configured to transmit a wavelength corresponding to green (G) are configured as Gr pixels. Sixteen (4×4) pixels provided with G color filters 221-Gb1 to Gb16 are configured as Gb pixels. Sixteen (4×4) pixels provided with B color filters 221-B1 to B16 configured to transmit a wavelength corresponding to blue (B) are configured as B pixels.

In FIG. 32, the pixel sections 200 each include the 16 (4×4) pixels 100 provided with the color filters 221 of the same color. Specifically, the 16 (4×4) R pixels form an R pixel section. The 16 (4×4) Gr pixels form a Gr pixel section, and the 16 (4×4) Gb pixels form a Gb pixel section. The 16 (4×4) B pixels form a B pixel section. The array pattern illustrated in FIG. 32 is repeatedly arranged in the pixel array section 21, and the R pixel sections, the Gr pixel sections, the Gb pixel sections, and the B pixel sections are disposed in a Bayer array.

In the R pixel section, a single on-chip micro lens 231 is disposed for R pixels surrounded by pixels of the same color (R pixels), that is, the 2×2 R pixels provided with the R color filters 221-R6, R7, R10, and R11. In the second embodiment, the structure in which the single on-chip micro lens 231 is shared by the 2×2 pixels 100 (color filters 221 thereof) is also referred to as a “2×2-OCL structure.” The 2×2 pixels 100 (four pixels) with a 2×2-OCL structure may be configured as pixels (normal pixels) configured to generate signals for generating captured images corresponding to light from objects or as pixels (phase difference pixels) configured to generate signals for performing phase difference detection.

Further, in the R pixel section, a single on-chip micro lens 232 is disposed for each R pixel adjacent to pixels of a different color (G pixels), that is, each of the 12 R pixels provided with the R color filters 221-R1 to R5, R8, R9, and R12 to R16. In the second embodiment, the structure in which the single on-chip micro lens 232 is disposed for the single pixel 100 (color filter 221 thereof) is also referred to as a “1×1-OCL structure.”

In this way, in the R pixel section, the R pixels surrounded by pixels of the same color (R pixels) have a 2×2-OCL structure, and the R pixels adjacent to pixels of a different color (G pixels) have 1×1-OCL structures. The R color filters 221 in a 2×2 array corresponding to a 2×2-OCL structure are separated from the surrounding R color filters 221 in a 1×1 array corresponding to a 1×1-OCL structure by CF separation sections 222. The R color filters 221 in a 1×1 array corresponding to a 1×1-OCL structure are separated from the other color filters 221 in a 1×1 array corresponding to a 1×1-OCL structure and the R color filters 221 in a 2×2 array corresponding to a 2×2-OCL structure by the CF separation sections 222.

Similarly, in the Gr pixel section, Gr pixels surrounded by pixels of the same color (Gr pixels) have a 2×2-OCL structure, and Gr pixels adjacent to pixels of a different color (R pixels or B pixels) have 1×1-OCL structures. In the Gb pixel section, Gb pixels surrounded by pixels of the same color (Gb pixels) have a 2×2-OCL structure, and Gb pixels adjacent to pixels of a different color (R pixels or B pixels) have 1×1-OCL structures. In the B pixel section, B pixels surrounded by pixels of the same color (B pixels) have a 2×2-OCL structure, and B pixels adjacent to pixels of a different color (G pixels) have 1×1-OCL structures.

With such a structure, it is possible to significantly reduce the difference in sensitivity between same-color pixels due to color mixing. Further, it is possible to significantly reduce the mixing of different colors due to trench separation scattering, thereby achieving a very high SNR (Signal-Noise Ratio).

Specifically, as illustrated in the cross-sectional view of FIG. 33, for example, in the Gr pixel section, when light (arrows L in the figure) incident on the on-chip micro lens 231 passes through the G color filters 221 and enters the Gr pixels (photoelectric conversion regions thereof), the light may be scattered by a trench formed as a pixel separation section 212. Even when such trench separation scattering occurs, since the Gr pixels with a 2×2-OCL structure is surrounded by the Gr pixels with 1×1-OCL structures, and the light thus enters the Gr pixels of the same color (photoelectric conversion regions thereof), it is possible to significantly reduce the mixing of different colors.

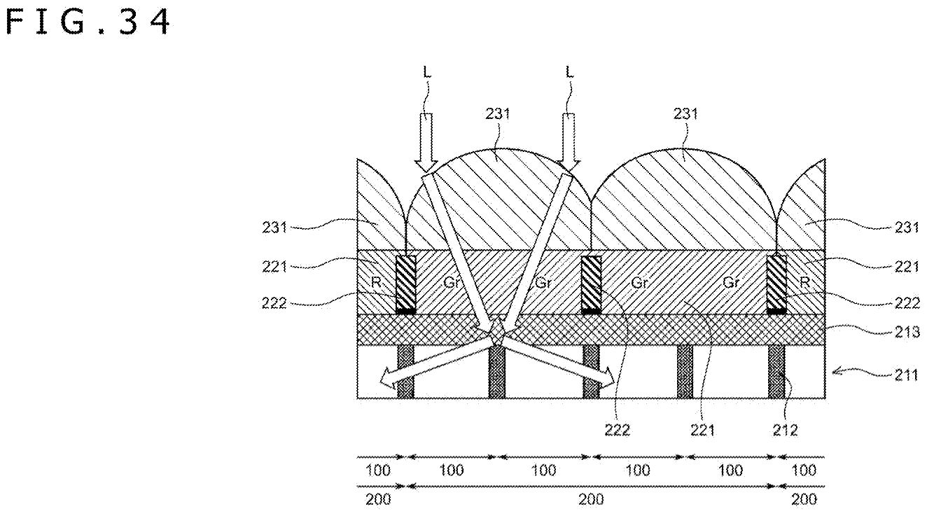

Meanwhile, in the cross-sectional view of FIG. 34, a structure of a case where the 16 pixels (4×4 pixels) of the same color in the pixel section 200 only have 2×2-OCL structures is illustrated for comparison. In this comparative structure, the 4×4 pixels in the pixel section 200 of the corresponding color are divided into four, and the single on-chip micro lens 231 is disposed for every 2×2 pixels, thereby forming four 2×2-OCL structures. As illustrated in the cross-sectional view of FIG. 34, for example, in the Gr pixel section, in a case where light (arrows L in the figure) incident on the on-chip micro lens 231 passes through the G color filters 221, and trench separation scattering occurs, since the pixels around the Gr pixels with a 2×2-OCL structure are pixels different from Gr pixels (for example, R pixels), the mixing of different colors due to trench separation scattering is more severe.

Further, as compared to the structure illustrated in the cross-sectional view of FIG. 34, the structure illustrated in the cross-sectional view of FIG. 33 includes 1×1-OCL structures and can thus enhance MTF (Modulation Transfer Function) to increase the resolution.

In FIG. 33, the pixels 100 each have a photoelectric conversion region formed in a silicon substrate 211. The pixels 100 are separated from other adjacent pixels by the pixel separation sections 212. The pixel separation sections 212 include element separation structures such as DTI. The G color filters 221 in a 2×2 array corresponding to a 2×2-OCL structure are separated from the G color filters 221 in a 1×1 array corresponding to a 1×1-OCL structure by the CF separation sections 222. The G color filters 221 in a 1×1 array corresponding to a 1×1-OCL structure are separated from the R color filters 221 in a 1×1 array corresponding to a 1×1-OCL structure by the CF separation sections 222. An anti-reflection film 213 is formed on an upper surface of the silicon substrate 211.

Here, a description has been given on the Gr pixel section, but this similarly applies to the R pixel section, the Gb pixel section, and the B pixel section. By applying 2×2-OCL structures to pixels surrounded by pixels of the same color and 1×1-OCL structures to pixels adjacent to pixels of different colors, it is possible to significantly reduce the difference in sensitivity between same-color pixels due to color mixing and also significantly reduce the mixing of different colors due to trench separation scattering.

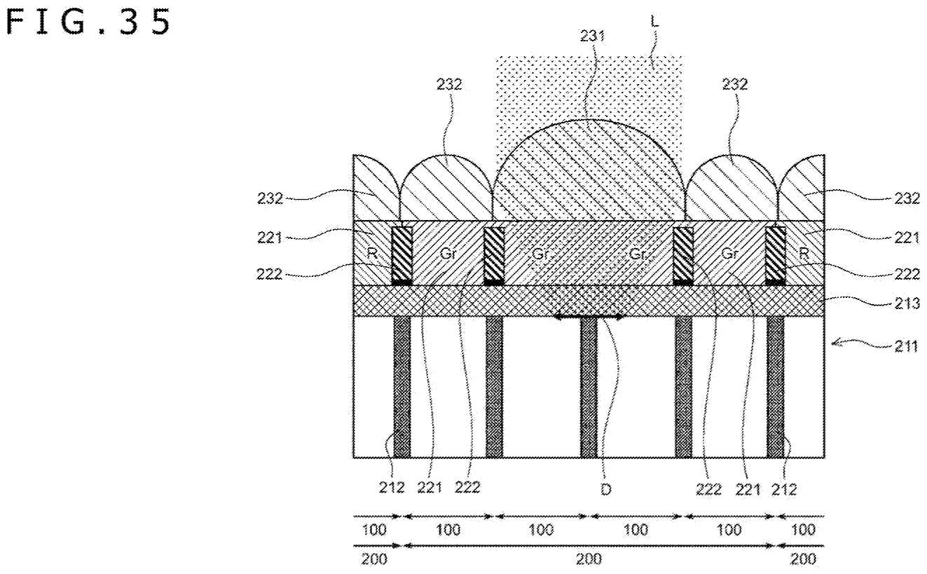

FIG. 35 is a cross-sectional view illustrating examples of the structures of the on-chip micro lenses 231 and 232 in the first example of the structure.

In the Gr pixel section, Gr pixels (2×2 pixels in the central part) surrounded by pixels of the same color (Gr pixels) have a 2×2-OCL structure, and Gr pixels (surrounding 12 pixels) adjacent to pixels of a different color (R pixels or B pixels) have 1×1-OCL structures. As illustrated in the cross-sectional view of FIG. 35, the height of the on-chip micro lens 231 disposed for a 2×2-OCL structure is greater than the height of the on-chip micro lenses 232 disposed for 1×1 OCL structures.

In this way, with the on-chip micro lenses 231 with a greater height, a spot diameter D of incident light (L in the figure) on the upper surface of the silicon substrate 211 can be reduced, thereby enhancing the separation ratio. Meanwhile, with the on-chip micro lenses 232 with a smaller height, the quantum efficiency (QE) can be enhanced. With this, the trade-off between the separation ratio regarding 2×2-OCL structures and the quantum efficiency (QE) regarding 1×1-OCL structures can be eliminated.

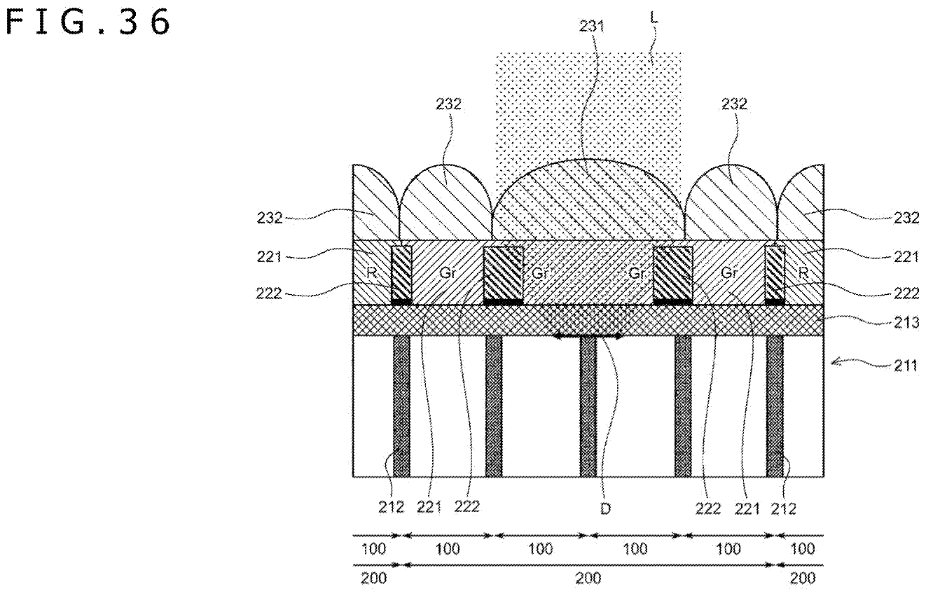

FIG. 36 is a cross-sectional view illustrating examples of the structures of the CF separation sections 222 in the first example of the structure.

In the Gr pixel section, Gr pixels (2×2 pixels in the central part) surrounded by pixels of the same color (Gr pixels) have a 2×2-OCL structure, and Gr pixels (surrounding 12 pixels) adjacent to pixels of a different color (R pixels or B pixels) have 1×1-OCL structures. As illustrated in the cross-sectional view of FIG. 36, the width of the CF separation sections 222 for separating the G color filters 221 in a 2×2 array corresponding to a 2×2-OCL structure from the surroundings is greater than the width of the CF separation sections 222 for separating the G color filters 221 in a 1×1 array corresponding to a 1×1-OCL structure from the surroundings.

In this way, with the CF separation sections 222 with a greater width at the periphery of the G color filters 221 in a 2×2 array, the light collection can be enhanced with the CF separation sections 222 including a low refractive index material or the like, thereby enhancing the separation ratio. Further, with the on-chip micro lenses 232 with a smaller height, the quantum efficiency (QE) can be enhanced. With this, the trade-off between the separation ratio regarding 2×2-OCL structures and the quantum efficiency (QE) regarding 1×1-OCL structures can be eliminated. Here, a description has been given on the Gr pixel section, but this similarly applies to the R pixel section, the Gb pixel section, and the B pixel section.

In the first example of the structure, the structure illustrated in the cross-sectional view of FIG. 35 or the structure illustrated in the cross-sectional view of FIG. 36 can be employed.

### Second Example of Structure

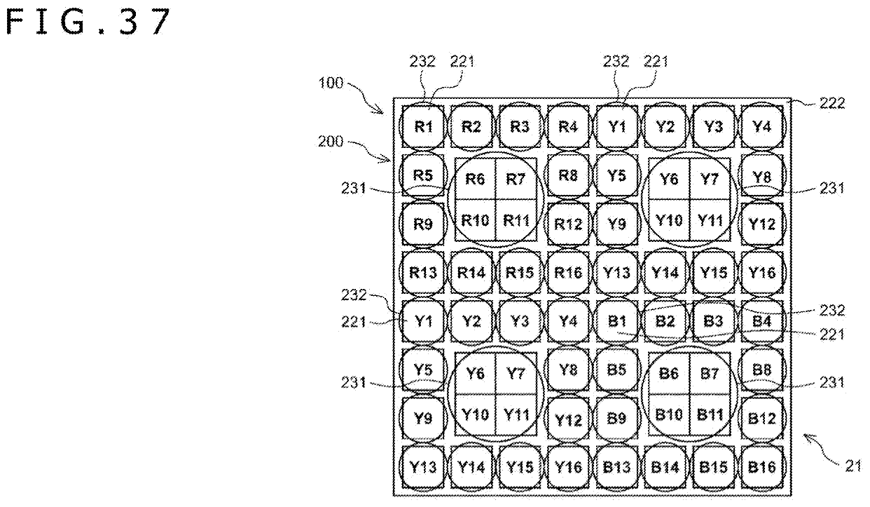

FIG. 37 is a plan view illustrating a second example of the structure to which the present disclosure is applied. In FIG. 37, parts corresponding to those of FIG. 32 are denoted by the same reference signs, and the descriptions thereof are appropriately omitted. In the following figures, the descriptions of parts with the same reference signs are appropriately omitted as well.

In FIG. 37, for the sake of description, identification information that combines abbreviations representing the colors of the color filters 221, namely, “R,” “Y,” and “B,” with numbers for identifying each region is described in regions corresponding to the color filters 221 disposed for the pixels 100.

As compared to the structure illustrated in the plane layout of FIG. 32, the structure illustrated in the plane layout of FIG. 37 has an RYYB array in which Y pixel sections are disposed instead of the Gr pixel section and the Gb pixel section disposed in a Bayer array.

Sixteen (4×4) pixels provided with Y color filters 221-Y1 to Y16 configured to transmit a wavelength corresponding to yellow (Y) are configured as Y pixels. The 16 (4×4) Y pixels form a Y pixel section. In the Y pixel section, Y pixels surrounded by pixels of the same color (Y pixels) have a 2×2-OCL structure, and Y pixels adjacent to pixels of a different color (R pixels or B pixels) have 1×1-OCL structures.

As described above, in the second example of the structure, in the pixel sections 200 of the corresponding colors disposed in an RYYB array, by applying 2×2-OCL structures to the pixels surrounded by the pixels of the same color and 1×1-OCL structures to the pixels adjacent to pixels of different colors, it is possible to reduce the difference in sensitivity between same-color pixels due to color mixing. Further, it is possible to reduce the mixing of different colors due to trench separation scattering, thereby improving SNR.

### Third Example of Structure

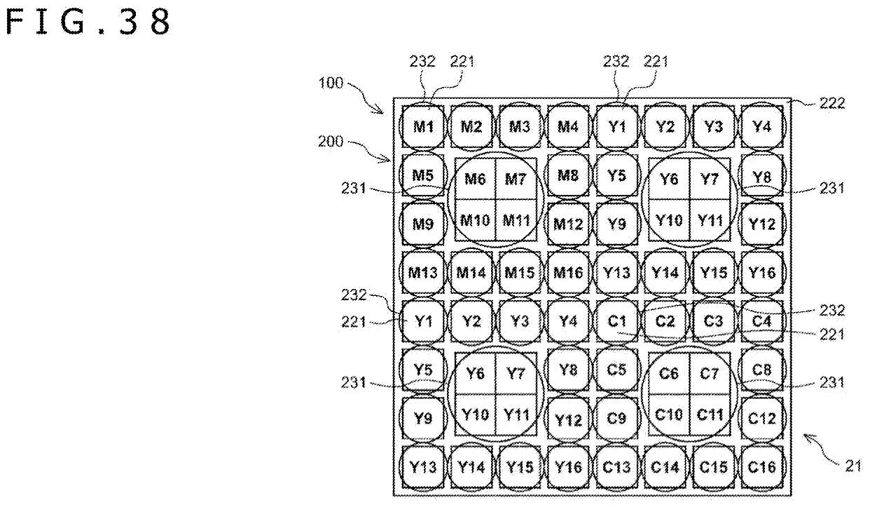

FIG. 38 is a plan view illustrating a third example of the structure to which the present disclosure is applied.

In FIG. 38, for the sake of description, identification information that combines abbreviations representing the colors of the color filters 221, namely, “C,” “M,” and “Y,” with numbers for identifying each region is described in regions corresponding to the color filters 221 disposed for the pixels 100.

As compared to the structure illustrated in the plane layout of FIG. 32, the structure illustrated in the plane layout of FIG. 38 has an MYYC array in which an M pixel section, Y pixel sections, and a C pixel section are disposed instead of the R pixel section, the Gr pixel section, the Gb pixel section, and the B pixel section disposed in a Bayer array.

Sixteen (4×4) pixels provided with M color filters 221-M1 to M16 configured to transmit a wavelength corresponding to magenta (M) are configured as M pixels. The 16 (4×4) M pixels form an M pixel section. In the M pixel section, M pixels surrounded by pixels of the same color (M pixels) have a 2×2-OCL structure, and M pixels adjacent to pixels of a different color (Y pixels) have 1×1-OCL structures.

Sixteen (4×4) pixels provided with the Y color filters 221-Y1 to Y16 configured to transmit a wavelength corresponding to yellow (Y) are configured as Y pixels. The 16 (4×4) Y pixels form a Y pixel section. In the Y pixel section, Y pixels surrounded by pixels of the same color (Y pixels) have a 2×2-OCL structure, and Y pixels adjacent to pixels of a different color (M pixels or C pixels) have 1×1-OCL structures.

Sixteen (4×4) pixels provided with C color filters 221-C1 to C16 configured to transmit a wavelength corresponding to cyan (C) are configured as C pixels. The 16 (4×4) C pixels form a C pixel section. In the C pixel section, C pixels surrounded by pixels of the same color (C pixels) have a 2×2-OCL structure, and C pixels adjacent to pixels of a different color (Y pixels) have 1×1-OCL structures.

As described above, in the third example of the structure, in the pixel sections 200 of the corresponding colors disposed in an MYYC array, by applying 2×2-OCL structures to the pixels surrounded by pixels of the same color and 1×1-OCL structures to the pixels adjacent to pixels of different colors, it is possible to reduce the difference in sensitivity between same-color pixels due to color mixing. Further, it is possible to reduce the mixing of different colors due to trench separation scattering, thereby improving SNR.

Note that, in FIG. 37 and FIG. 38, the CMY color filters have been exemplified as the color filters 221 other than RGB color filters, but the present disclosure is not limited to this, and other color filters may be used. Further, the C pixel sections, the M pixel sections, and the Y pixel sections are examples of the pixel sections 200 of colors other than RGB, and the pixel sections 200 of another color, such as structures using W pixel sections including W pixels corresponding to white (W), for example, may be employed. Not only RGB color filters, but also color filters of CMY or the like can be used to enhance the quantum efficiency (QE).

### Fourth Example of Structure

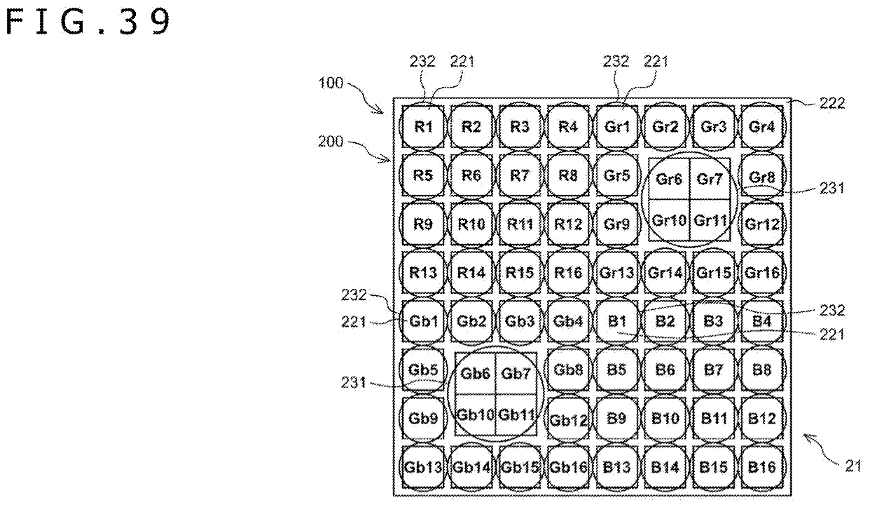

FIG. 39 is a plan view illustrating a fourth example of the structure to which the present disclosure is applied.

In the structure illustrated in the plane layout of FIG. 39, as compared to the structure illustrated in the plane layout of FIG. 32, the 2×2-OCL structures in the central parts of the R pixel section and the B pixel section are changed to 1×1-OCL structures, thereby increasing the proportion of 1×1-OCL structures.

In the Gr pixel section and the Gb pixel section, pixels surrounded by pixels of the same color have 2×2-OCL structures, and pixels adjacent to pixels of different colors have 1×1-OCL structures.

Meanwhile, in the R pixel section, R pixels surrounded by pixels of the same color (R pixels) and R pixels adjacent to pixels of a different color (Gr pixels or Gb pixels), that is, all the R pixels, have 1×1-OCL structures. In the B pixel section, B pixels surrounded by pixels of the same color (B pixels) and B pixels adjacent to pixels of a different color (Gr pixels or Gb pixels), that is, all the B pixels, have 1×1-OCL structures.

As described above, in the fourth example of the structure, among the pixel sections 200 disposed in a Bayer array, the Gr pixel section and the Gb pixel section have 2×2-OCL structures, while the R pixel section and the B pixel section do not have 2×2-OCL structures and only have 1×1-OCL structures. This can increase the proportion of 1×1-OCL structures to the entire structure. By increasing the proportion of 1×1-OCL structures, it is possible to enhance

MTF to increase the resolution. Thus, in a case where resolution is prioritized, it is sufficient to employ the fourth example of the structure to use, rather than using all the pixel sections 200 as phase difference pixel sections configured to acquire phase difference information, at least some of the pixel sections 200 as phase difference pixel sections.

### Fifth Example of Structure

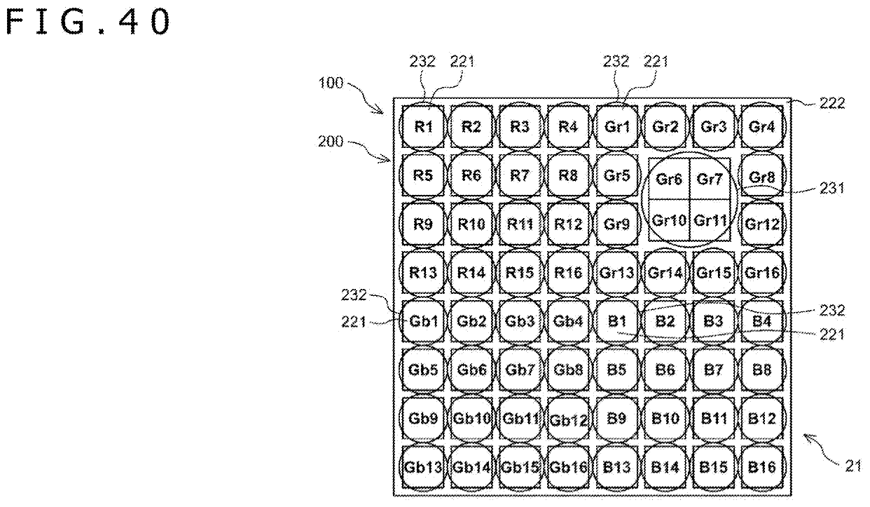

FIG. 40 is a plan view illustrating a fifth example of the structure to which the present disclosure is applied.

In the structure illustrated in the plane layout of FIG. 40, as compared to the structure illustrated in the plane layout of FIG. 39, in addition to the R pixel section and the B pixel section, the 2×2-OCL structure in the central part of the Gb pixel section is also changed to a 1×1-OCL structure, thereby further increasing the proportion of 1×1-OCL structures.

In the Gr pixel section, pixels surrounded by pixels of the same color have a 2×2-OCL structure, and pixels adjacent to pixels of different colors have 1×1-OCL structures. Meanwhile, in the R pixel section, the B pixel section, and the Gb pixel section, pixels surrounded by pixels of the same color and pixels adjacent to pixels of different colors, that is, all the pixels, have 1×1-OCL structures.

As described above, in the fifth example of the structure, among the pixel sections 200 disposed in a Bayer array, the Gr pixel section has a 2×2-OCL structure, while the R pixel section, the B pixel section, and the Gb pixel section do not have 2×2-OCL structures and only have 1×1-OCL structures. This can increase the proportion of 1×1-OCL structures to the entire structure. By increasing the proportion of 1×1-OCL structures, it is possible to increase the resolution.

Note that, in FIG. 39 and FIG. 40, the case where the R pixel section and the B pixel section have 1×1-OCL structures has been described, but it is not necessary for all the R pixel sections and the B pixel sections disposed in the pixel array section 21 to have 1×1-OCL structures. Some of the R pixel sections and the B pixel sections may only have 1×1-OCL structures, while the remaining R pixel sections and B pixel sections may have 2×2-OCL structures and 1×1-OCL structures. It may be possible to dispose 2×2-OCL structures in some places, and the proportions of 2×2-OCL structures and 1×1-OCL structures to the entire structure are determined as desired.

### Sixth Example of Structure

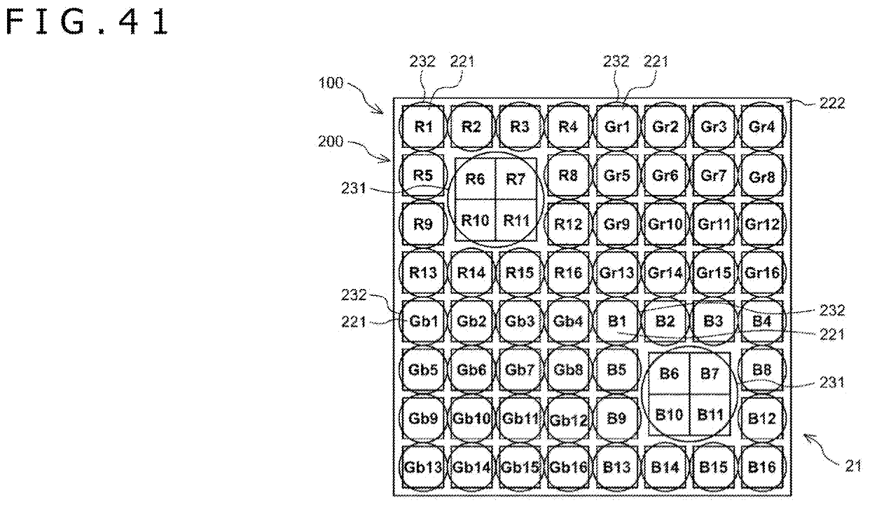

FIG. 41 is a plan view illustrating a sixth example of the structure to which the present disclosure is applied.

In the structure illustrated in the plane layout of FIG. 41, as compared to the structure illustrated in the plane layout of FIG. 32, the 2×2-OCL structures in the central parts of the Gr pixel section and the Gb pixel section are changed to 1×1-OCL structures such that only four pixels in the central part of each of the R pixel section and B pixel section have a 2×2-OCL structure.

In the R pixel section and the B pixel section, pixels surrounded by pixels of the same color have 2×2-OCL structures, while pixels adjacent to pixels of different colors have 1×1-OCL structures. Meanwhile, in the Gr pixel section and the Gb pixel section, pixels surrounded by pixels of the same color and pixels adjacent to pixels of different colors, that is, all the pixels, have 1×1-OCL structures.

As described above, in the sixth example of the structure, among the pixel sections 200 disposed in a Bayer array, the R pixel section and the B pixel section have 2×2-OCL structures, while the Gr pixel section and the Gb pixel section do not have 2×2-OCL structures and only have 1×1-OCL structures. This can increase the sensitivity of the R pixel section and the B pixel section. That is, since the R pixel section and the B pixel section are relatively less sensitive than the Gr pixel section and the Gb pixel section, 2×2-OCL structures are applied to the four pixels in each central part to increase the sensitivity.

### Seventh Example of Structure

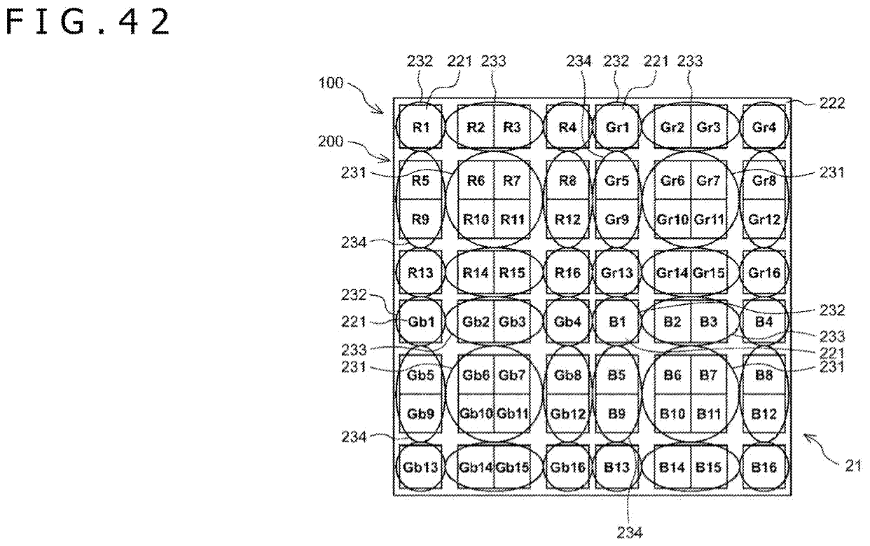

FIG. 42 is a plan view illustrating a seventh example of the structure to which the present disclosure is applied.

In the structure illustrated in the plane layout of FIG. 42, as compared to the structure illustrated in the plane layout of FIG. 32, some of the 1×1-OCL structures in the pixel sections 200 of the corresponding colors are changed to 1×2-OCL structures or 2×1-OCL structures, thereby obtaining phase difference information from pixels adjacent to pixels of different colors.

In the R pixel section, R pixels surrounded by pixels of the same color (R pixels) have a 2×2-OCL structure, and R pixels adjacent to pixels of a different color (Gr pixels or Gb pixels) have any of 1×1-OCL structures, 1×2-OCL structures, and 2×1-OCL structures.

Specifically, for the 2×2 R pixels (four pixels) provided with the R color filters 221-R6, R7, R10, and R11, the single on-chip micro lens 231 is disposed over the entire area, thereby forming a 2×2-OCL structure. For each R pixel (one pixel) provided with the R color filter 221-R1, R4, R13, or R16, the single on-chip micro lens 232 is disposed, thereby forming 1×1-OCL structures.

For the 1×2 R pixels (two pixels) provided with the R color filters 221-R2 and R3, a single on-chip micro lens 233 is disposed, thereby forming a 1×2-OCL structure. Similarly, the 1×2 R pixels (two pixels) provided with the R color filters 221-R14 and R15 have a 1×2-OCL structure. In the second embodiment, the structure in which the single on-chip micro lens 233 is shared by the 1×2 pixels 100 (color filters 221 thereof) is also referred to as a “1×2-OCL structure.”

For the 2×1 R pixels (two pixels) provided with the R color filters 221-R5 and R9, a single on-chip micro lens 234 is disposed, thereby forming a 2×1-OCL structure. Similarly, the 2×1 R pixels (two pixels) provided with the R color filters 221-R8 and R12 have a 2×1-OCL structure. In the second embodiment, the structure in which the single on-chip micro lens 234 is shared by the 2×1 pixels 100 (color filters 221 thereof) is also referred to as a “2×1-OCL structure.”

In the R pixel section, phase difference information can be obtained by using the R pixels with a 2×2-OCL structure as phase difference pixels. However, in a case where it is desired to increase the number of phase difference pixels, the 1×1-OCL structures can be changed to 1×2-OCL structures or 2×1-OCL structures to utilize the R pixels with 1×2-OCL structures or 2×1-OCL structures as phase difference pixels.

Similarly, in the Gr pixel section, the Gb pixel section, and the B pixel section, pixels surrounded by pixels of the same color have 2×2-OCL structures, and pixels adjacent to pixels of different colors have any of 1×1-OCL structures, 1×2-OCL structures, and 2×1-OCL structures.

As described above, in the seventh example of the structure, in the pixel sections 200 disposed in a Bayer array, by applying 2×2-OCL structures to the pixels surrounded by pixels of the same color and including 1×2-OCL structures or 2×1-OCL structures as the structures of the pixels adjacent to pixels of different colors, it is possible to increase the number of phase difference pixels. Employing the structure illustrated in the plane layout of FIG. 42 does not result in a significant increase in the mixing of different colors due to trench separation scattering.

### Eighth Example of Structure

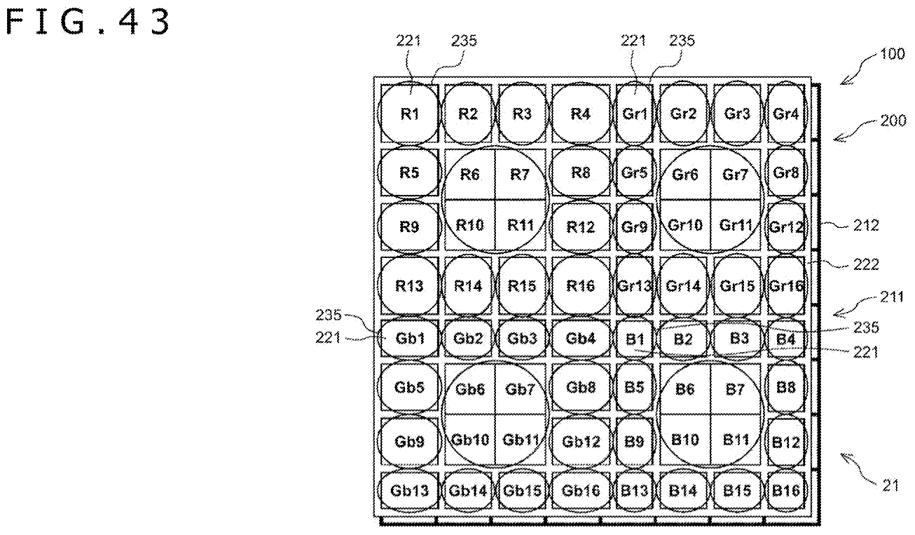

FIG. 43 is a plan view illustrating an eighth example of the structure to which the present disclosure is applied.

As compared to the structure illustrated in the plane layout of FIG. 32, the structure illustrated in the plane layout of FIG. 43 is a structure in which the positions and sizes of the color filter 221, the CF separation section 222, and an on-chip micro lens 235 are different between the pixels 100 or the pixel sections 200.

In the R pixel section, the R color filter 221 and the on-chip micro lens 235 disposed for each R pixel have positions and sizes different between the R pixels. Similarly, in the Gr pixel section, the Gb pixel section, and the B pixel section, the color filter 221 and the on-chip micro lens 235 disposed for each pixel have positions and sizes different between the pixels. Further, the CF separation sections 222 formed between the color filters 221 have positions and sizes different between the pixels.

With the structure in which the positions and sizes of the color filters 221, the CF separation sections 222, and the on-chip micro lenses 235 are different between the pixels 100, which are R pixels, Gr pixels, Gb pixels, or B pixels, the structure in which the positions and sizes of the color filters 221, the CF separation sections 222, and the on-chip micro lenses 235 are different between the pixel sections 200, which are R pixel sections, Gr pixel sections, Gb pixel sections, or B pixel sections is achieved.

As described above, in the eighth example of the structure, with the structure in which the positions and sizes of the color filters 221, the CF separation sections 222, and the on-chip micro lenses 235 are different between the pixels 100 or the pixel sections 200, it is also possible to reduce the difference in sensitivity between same-color pixels due to mixed color components other than trench separation scattering.

Note that all the structures of the color filters 221, the CF separation sections 222, and the on-chip micro lenses 235 may be different between the pixels 100 or the pixel sections 200, as a matter of course, or at least one of the structures may be different. Further, in changing the structures, it is sufficient to change at least either the positions or the sizes to be different. That is, it is sufficient that the positions or sizes of the pixel sections 200 of the corresponding colors are different as a whole.

### Ninth Example of Structure

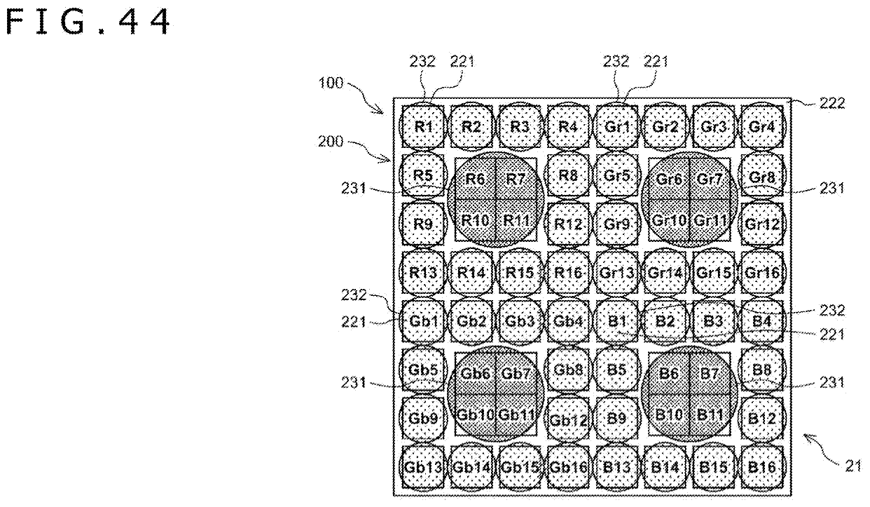

FIG. 44 is a plan view illustrating a ninth example of the structure to which the present disclosure is applied.

As compared to the structure illustrated in the plane layout of FIG. 32, the structure illustrated in the plane layout of FIG. 44 is a structure in which the refractive index of the on-chip micro lenses 231 disposed for 2×2-OCL structures is different from the refractive index of the on-chip micro lenses 232 disposed for 1×1-OCL structures.

In the R pixel section, the effective refractive index of the single on-chip micro lens 231 disposed for the 2×2 R pixels provided with the R color filters 221-R6, R7, R10, and R11 is higher than the effective refractive index of the 12 on-chip micro lenses 232 disposed for the respective 12 R pixels provided with the R color filters 221-R1 to R5, R8, R9, and R12 to R16.

Similarly, in the Gr pixel section, the Gb pixel section, and the B pixel section, the effective refractive index of the on-chip micro lenses 231 disposed for 2×2-OCL structures including pixels surrounded by pixels of the same color is higher than the effective refractive index of the on-chip micro lenses 232 disposed for 1×1-OCL structures.

As described above, in the ninth example of the structure, in the pixel sections 200 of the corresponding colors, by making the effective refractive index of the on-chip micro lenses 231 for 2×2-OCL structures higher than the effective refractive index of the on-chip micro lenses 232 for 1×1-OCL structures, it is possible to ensure the separation ratio.

### Tenth Example of Structure

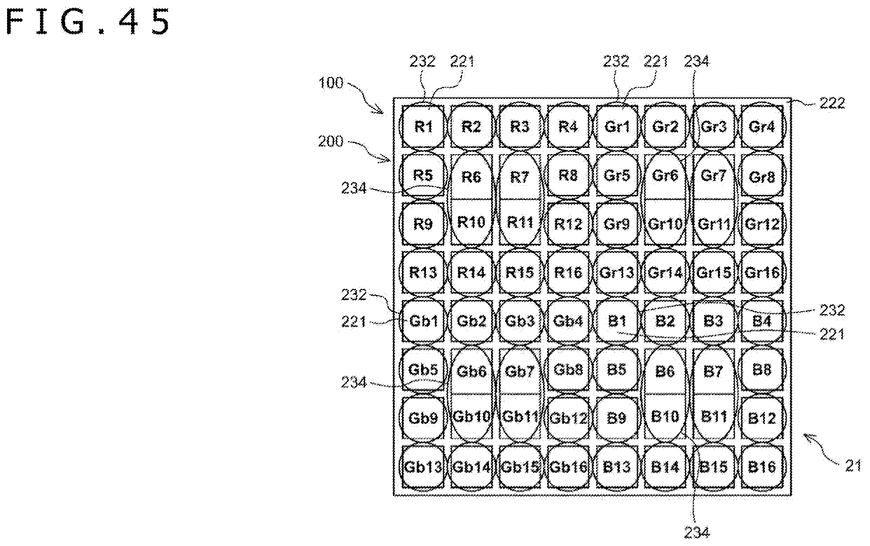

FIG. 45 to FIG. 48 are plan views illustrating a tenth example of the structure to which the present disclosure is applied.

In the structure illustrated in the plane layout of FIG. 45, as compared to the structure illustrated in the plane layout of FIG. 32, the 2×2-OCL structures in the central parts of the pixel sections 200 of the corresponding colors are changed to 2×1-OCL structures, thereby obtaining phase difference information from pixels surrounded by pixels of the same color.

In the R pixel section, R pixels surrounded by pixels of the same color (R pixels) have 2×1-OCL structures, and R pixels adjacent to pixels of a different color (Gr pixels or Gb pixels) have 1×1-OCL structures.

Specifically, for the 2×1 R pixels (two pixels) provided with the R color filters 221-R6 and R10, the on-chip micro lens 234 is disposed, thereby forming a 2×1-OCL structure. Similarly, for the 2×1 R pixels (two pixels) provided with the R color filters 221-7 and R11, the on-chip micro lens 234 is disposed, thereby forming a 2×1-OCL structure. For each of the R pixels (12 pixels) provided with the R color filters 221-R1 to R5, R8, R9, and R12 to R16, the on-chip micro lens 232 is disposed, thereby forming 1×1-OCL structures.

Similarly, in the Gr pixel section, the Gb pixel section, and the B pixel section, pixels surrounded by pixels of the same color have 2×1-OCL structures, and pixels adjacent to pixels of different colors have 1×1-OCL structures.

As described above, in the tenth example of the structure, in the pixel sections 200 disposed in a Bayer array, the pixels surrounded by pixels of the same color have 2×1-OCL structures, thereby allowing two pairs of the pixels with 2×1-OCL structures disposed side by side in the row direction to be utilized as phase difference pixels.

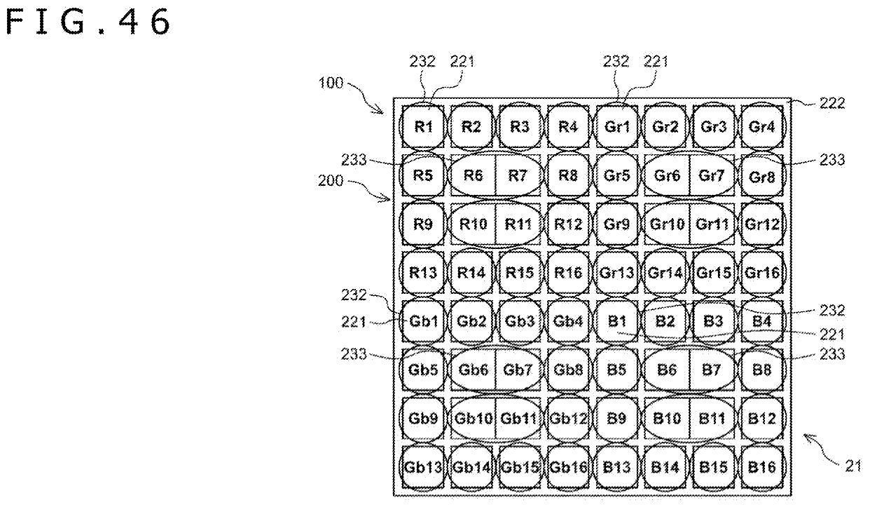

Note that, in the structure illustrated in the plane layout of FIG. 45, the pixels surrounded by pixels of the same color have 2×1-OCL structures, but the pixels surrounded by pixels of the same color may have 1×2-OCL structures as illustrated in the plane layout of FIG. 46. In FIG. 46, two pairs of pixels with 1×2-OCL structures disposed side by side in the column direction can be utilized as phase difference pixels.

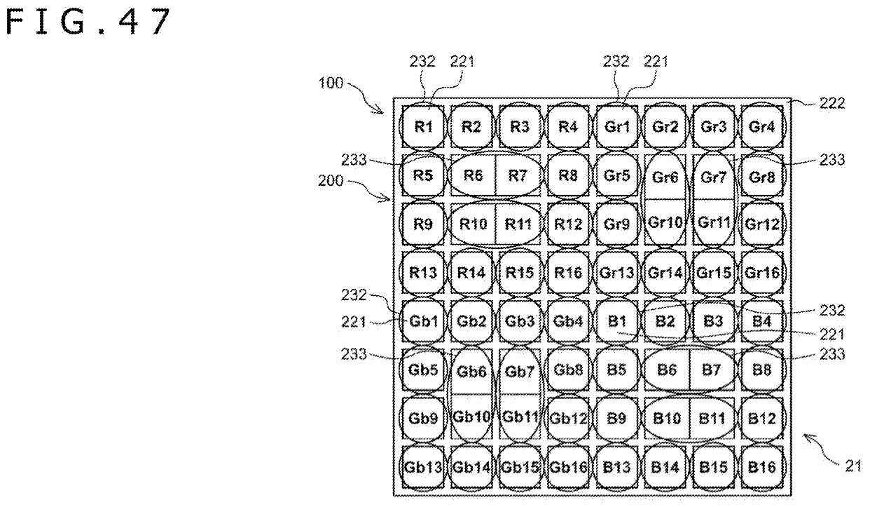

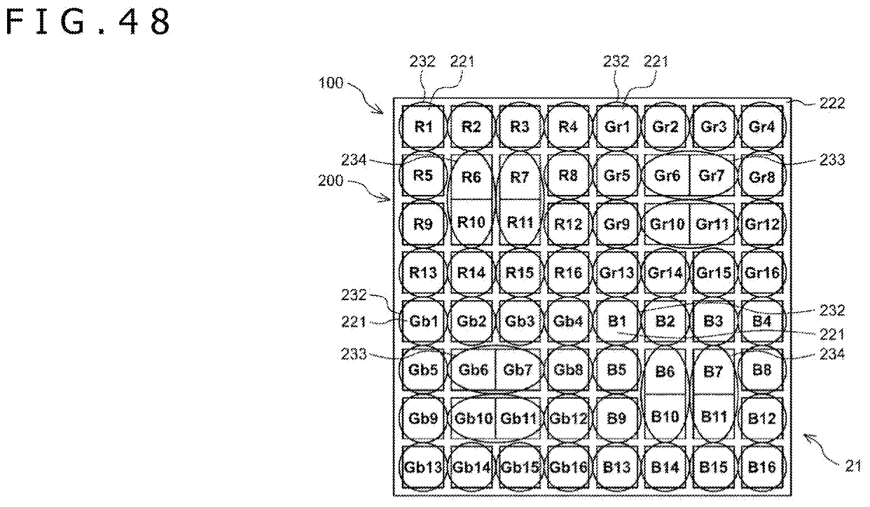

Further, as illustrated in the plane layouts of FIG. 47 and FIG. 48, any of a 2×1-OCL structure or a 1×2-OCL structure may be employed for each of the pixel sections 200 of the corresponding colors, thereby forming a combined structure of a 2×1-OCL structure and a 1×2-OCL structure. In FIG. 47, while four pixels in the central part of each of the R pixel section and the B pixel section have 1×2-OCL structures, four pixels in the central part of each of the Gr pixel section and the Gb pixel section have 2×1-OCL structures. In FIG. 48, while four pixels in the central part of each of the R pixel section and the B pixel section have 2×1-OCL structures, four pixels in the central part of each of the Gr pixel section and the Gb pixel section have 1×2-OCL structures.

### Eleventh Example of Structure

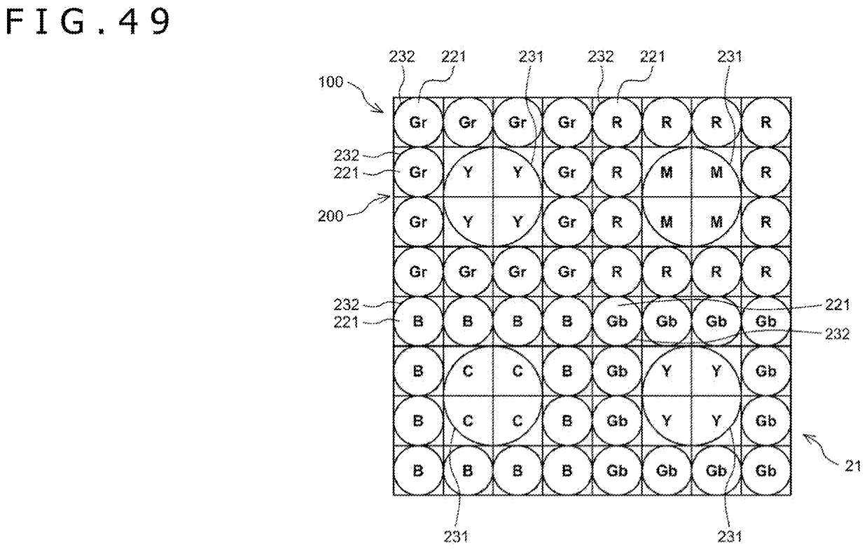

FIG. 49 to FIG. 55 are plan views illustrating an eleventh example of the structure to which the present disclosure is applied.

In the pixel sections 200 of the corresponding colors, the colors of the color filter 221 can be different between phase difference pixels for acquiring phase difference information and pixels other than those pixels. In this regard, by combining the color filters 221 corresponding to red (R), green (G), and blue (B) with the color filters 221 corresponding to other colors, it is possible to ensure the color reproducibility. As other colors, for example, cyan (C), magenta (M), yellow (Y), white (W), and greenish colors such as emerald (E) and wide green, can be used to enhance the sensitivity.

### (A) Example 1

As illustrated in the plane layout of FIG. 49, in a case where, in each of the pixel sections 200, four pixels in the central part, which have a 2×2-OCL structure, are used as phase difference pixels, the colors of the color filters 221 can be different between the four pixels with a 2×2-OCL structure and the surrounding 12 pixels with 1×1-OCL structures.

Specifically, among the four pixel sections 200, in the upper-left and lower-right pixel sections 200, the Y color filters 221 are disposed for four pixels with a 2×2-OCL structure, and the G color filters 221 are disposed for the surrounding 12 pixels with 1×1-OCL structures.

Further, in the upper-right pixel section 200, the M color filters 221 are disposed for four pixels with a 2×2-OCL structure, and the R color filters 221 are disposed for the surrounding 12 pixels with 1×1-OCL structures. In the lower-left pixel section 200, the C color filters 221 are disposed for four pixels with a 2×2-OCL structure, and the B color filters 221 are disposed for the surrounding 12 pixels with 1×1-OCL structures.

### (B) Example 2

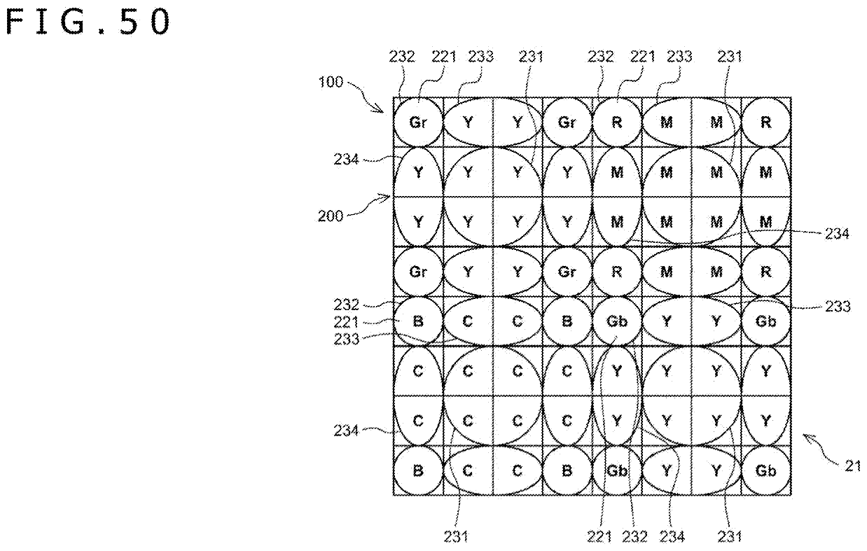

As illustrated in the plane layout of FIG. 50, in a case where, in each of the pixel sections 200, four pixels in the central part, which have a 2×2-OCL structure, two pairs of pixels in the upper and lower parts of the central part, which have a 1×2-OCL structure, and two pairs of pixels in the left and right parts of the central part, which have a 2×1-OCL structure, are used as phase difference pixels, the colors of the color filters 221 can be different between the 12 pixels with a 2×2-OCL structure, 1×2-OCL structures, and 2×1-OCL structures, and the other four pixels with 1×1-OCL structures.

Specifically, among the four pixel sections 200, in the upper-left and lower-right pixel sections 200, the Y color filters 221 are disposed for 12 pixels with a 2×2-OCL structure, 1×2-OCL structures, and 2×1-OCL structures, and the G color filters 221 are disposed for four pixels with 1×1-OCL structures.

Further, in the upper-right pixel section 200, the M color filters 221 are disposed for 12 pixels with a 2×2-OCL structure, 1×2-OCL structures, and 2×1-OCL structures, and the R color filters 221 are disposed for four pixels with 1×1-OCL structures. In the lower-left pixel section 200, the C color filters 221 are disposed for 12 pixels with a 2×2-OCL structure, 1×2-OCL structures, and 2×1-OCL structures, and the B color filters 221 are disposed for four pixels with 1×1-OCL structures.

### (C) Example 3

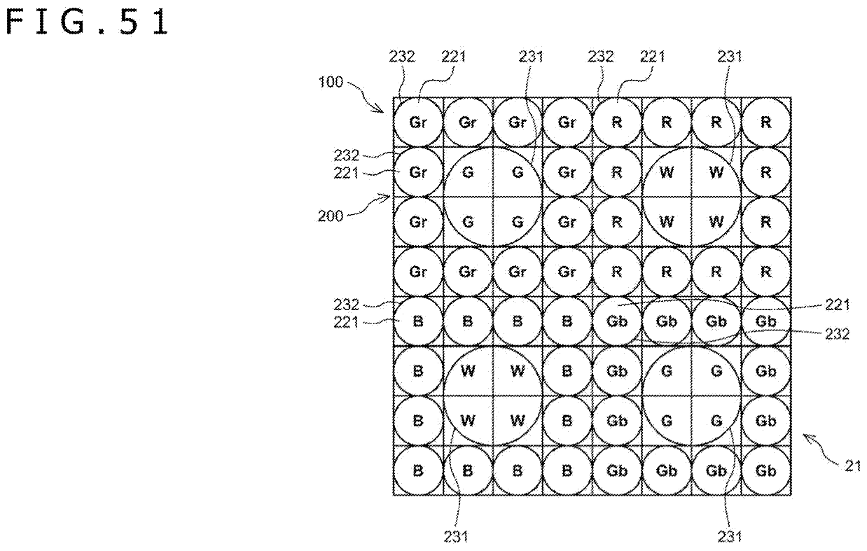

As illustrated in the plane layout of FIG. 51, in a case where, in each of the pixel sections 200, four pixels in the central part, which have a 2×2-OCL structure, are used as phase difference pixels, the colors of the color filters 221 can be different between the four pixels with a 2×2-OCL structure and the surrounding 12 pixels with 1×1-OCL structures.

Specifically, among the four pixel sections 200, in the upper-left and lower-right pixel sections 200, the G color filters 221 of a greenish color are disposed for four pixels with a 2×2-OCL structure, and the G color filters 221 are disposed for the surrounding 12 pixels with 1×1-OCL structures.

Further, in the upper-right pixel section 200, four pixels with a 2×2-OCL structure are

W pixels with no color filter, and the R color filters 221 are disposed for the surrounding 12 pixels with 1×1-OCL structures. In the lower-left pixel section 200, four pixels with a 2×2-OCL structure are W pixels with no color filter, and the B color filters 221 are disposed for the surrounding 12 pixels with 1×1-OCL structures.

### (D) Example 4

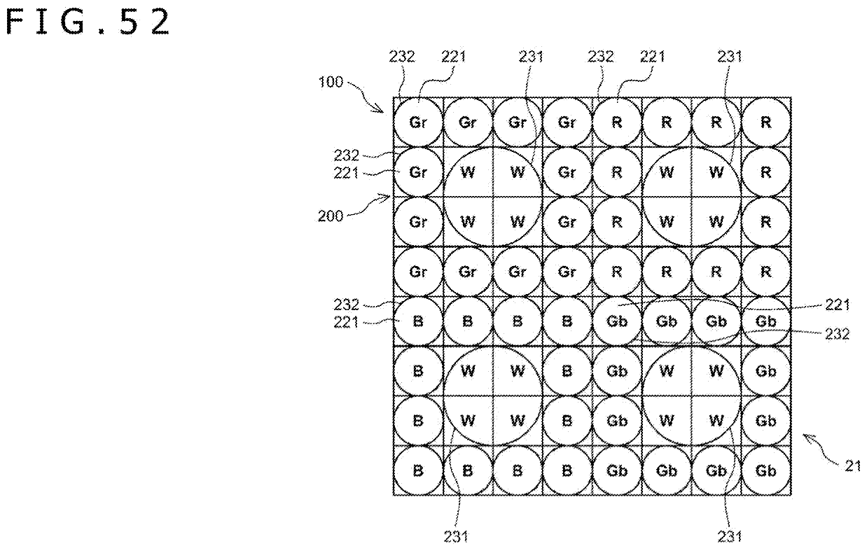

As illustrated in the plane layout of FIG. 52, in a case where, in each of the pixel sections 200, four pixels in the central part, which have a 2×2-OCL structure, are used as phase difference pixels, the colors of the color filters 221 can be different between the four pixels with a 2×2-OCL structure and the surrounding 12 pixels with 1×1-OCL structures.

Specifically, in the four pixel sections 200, four pixels with a 2×2-OCL structure are W pixels with no color filter. In the upper-left and lower-right pixel sections 200, the G color filters 221 are disposed for 12 pixels with 1×1-OCL structures. In the upper-right pixel section 200, the R color filters 221 are disposed for 12 pixels with 1×1-OCL structures. In the lower-left pixel section 200, the B color filters 221 are disposed for 12 pixels with 1×1-OCL structures.

### (E) Example 5

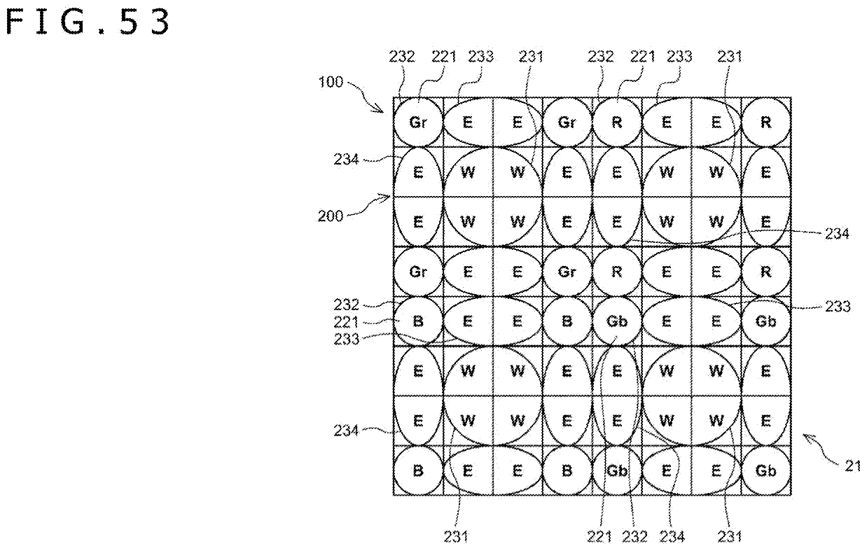

As illustrated in the plane layout of FIG. 53, in a case where, in each of the pixel sections 200, four pixels in the central part, which have a 2×2-OCL structure, or two pairs of pixels in the upper and lower parts of the central part, which have a 1×2-OCL structure, and two pairs of pixels in the left and right parts of the central part, which have a 2×1-OCL structure, are used as phase difference pixels, the colors of the color filters 221 can be different between the 12 pixels with a 2×2-OCL structure, 1×2-OCL structures, and 2×1-OCL structures, and the other four pixels with 1×1-OCL structures.

In the four pixel sections 200, four pixels with a 2×2-OCL structure are W pixels with no color filter, and E color filters 221 are disposed for eight pixels with 1×2-OCL structures and 2×1-OCL structures.

In the upper-left and lower-right pixel sections 200, the G color filters 221 are disposed for four pixels with 1×1-OCL structures. In the upper-right pixel section 200, the R color filters 221 are disposed for four pixels with 1×1-OCL structures. In the lower-left pixel section 200, the B color filters 221 are disposed for four pixels with 1×1-OCL structures.

### (F) Example 6

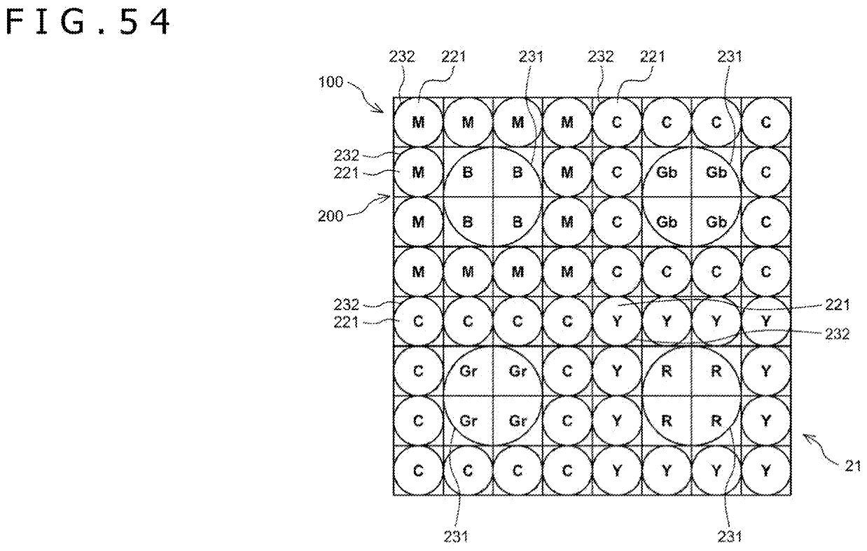

As illustrated in the plane layout of FIG. 54, in a case where, in each of the pixel sections 200, four pixels in the central part, which have a 2×2-OCL structure, are used as phase difference pixels, the colors of the color filters 221 can be different between the four pixels with a 2×2-OCL structure and the surrounding 12 pixels with 1×1-OCL structures.

Specifically, among the four pixel sections 200, in the upper-right and lower-left pixel sections 200, the G color filters 221 are disposed for four pixels with a 2×2-OCL structure, and the C color filters 221 are disposed for the surrounding 12 pixels with 1×1-OCL structures.

Further, in the upper-left pixel section 200, the B color filters 221 are disposed for four pixels with a 2×2-OCL structure, and the M color filters 221 are disposed for the surrounding 12 pixels with 1×1-OCL structures. In the lower-right pixel section 200, the R color filters 221 are disposed for four pixels with a 2×2-OCL structure, and the Y color filters 221 are disposed for the surrounding 12 pixels with 1×1-OCL structures.

### (G) Example 7

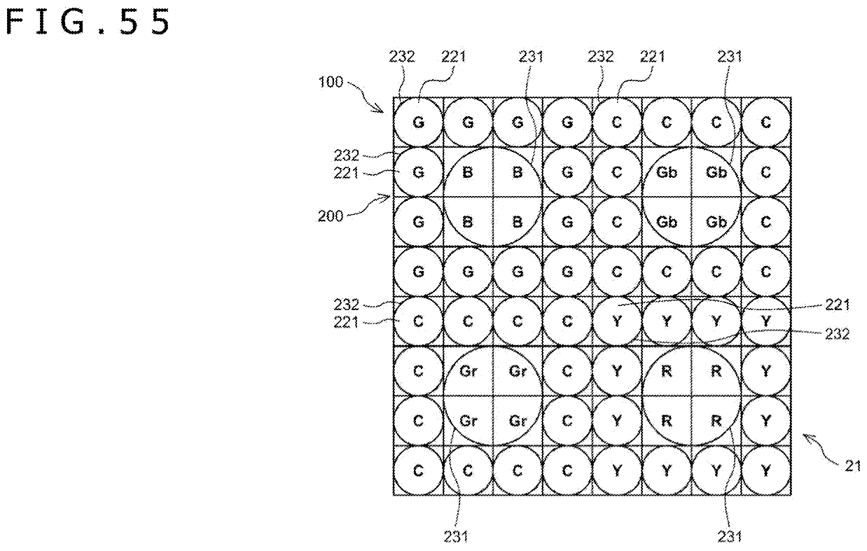

As illustrated in the plane layout of FIG. 55, in a case where, in each of the pixel sections 200, four pixels in the central part, which have a 2×2-OCL structure, are used as phase difference pixels, the colors of the color filters 221 can be different between the four pixels with a 2×2-OCL structure and the surrounding 12 pixels with 1×1-OCL structures.

Specifically, among the four pixel sections 200, in the upper-right and lower-left pixel sections 200, the G color filters 221 are disposed for four pixels with a 2×2-OCL structure, and the C color filters 221 are disposed for the surrounding 12 pixels with 1×1-OCL structures.

Further, in the upper-left pixel section 200, the B color filters 221 are disposed for four pixels with a 2×2-OCL structure, and the G color filters 221 are disposed for the surrounding 12 pixels with 1×1-OCL structures. In the lower-right pixel section 200, the R color filters 221 are disposed for four pixels with a 2×2-OCL structure, and the Y color filters 221 are disposed for the surrounding 12 pixels with 1×1-OCL structures.

As described above, in the eleventh example of the structure, by making the colors of the color filters 221 different between the phase difference pixels for acquiring phase difference information and the pixels other than those pixels, for example, the color reproducibility is ensured, or sensitivity enhancement is achieved.

Note that, in the second embodiment, as the pixel sections 200 of the corresponding colors, the structure including 4×4 pixels corresponding to color filters of the same color in a 4×4 array has been exemplified, but the present disclosure can be applied to the pixel section 200 including n×n pixels corresponding to color filters of the same color in an n×n array (n is an integer of 2 or more). That is, in the present disclosure, the pixel sections 200 of the corresponding colors each include n×n pixels corresponding to color filters of the same color in an n×n array such that, in the pixel sections 200 of the corresponding colors, pixels surrounded by pixels of the same color have an on-chip micro lens arrangement in a structure different from that of pixels adjacent to pixels of different colors.

### 3. Modified Example

The structures to which the present disclosure is applied described above are examples. The structure of any of the first to fourteenth examples of the structure of the first embodiment may be combined with any other structure. Further, the structure of any of the first to eleventh examples of the structure of the second embodiment may be combined with any other structure.

The solid-state image pickup device 10 can be a CMOS solid-state image pickup device with a back-illuminated structure that light enters from the upper layer (back surface side) opposite to the wiring layer side (front surface side) formed as a lower layer when viewed from the silicon substrate having formed therein the photoelectric conversion regions. Note that the solid-state image pickup device 10 may have a front-illuminated structure that light enters from the wiring layer side (front surface side).

Note that the structures to which the present disclosure is applied can be applied not only to CMOS solid-state image pickup devices but also to other solid-state image pickup devices such as CCD (Charge Coupled Device) solid-state image pickup devices.

### Configuration of Electronic Apparatus

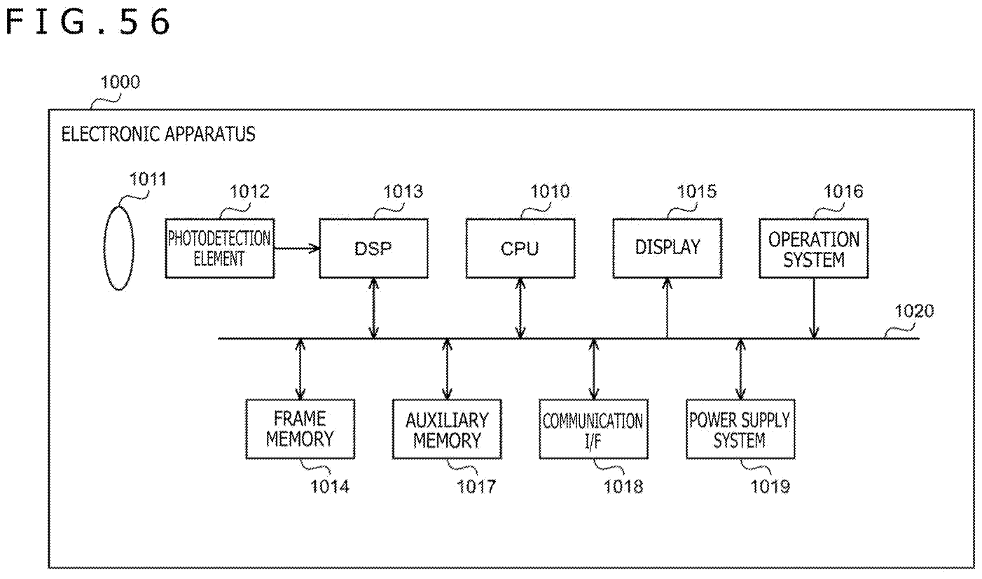

The photodetector to which the present disclosure is applied can be mounted on electronic apparatuses such as smartphones, tablet devices, cell phones, digital still cameras, and digital video cameras. FIG. 56 is a block diagram illustrating a configuration example of an electronic apparatus having mounted thereon a photodetector to which the present disclosure is applied.

In FIG. 56, an electronic apparatus 1000 includes an image pickup system including an optical system 1011 including a lens group, a photodetection element 1012 having functions and structures corresponding to the solid-state image pickup device 10 of FIG. 1, and a DSP (Digital Signal Processor) 1013 that is a camera signal processing unit. In the electronic apparatus 1000, other than the image pickup system, a CPU (Central Processing Unit) 1010, a frame memory 1014, a display 1015, an operation system 1016, an auxiliary memory 1017, a communication I/F 1018, and a power supply system 1019 are connected to each other through a bus 1020.

The CPU 1010 controls operation of each unit of the electronic apparatus 1000.

The optical system 1011 captures incident light (image light) from an object and forms an image of the incident light on a photodetection surface of the photodetection element 1012. The photodetection element 1012 converts the light amount of incident light, an image of which has been formed on the photodetection surface by the optical system 1011, into electrical signals on a pixel-by-pixel basis and outputs the electrical signals as pixel signals. The DSP 1013 performs predetermined signal processing on signals output from the photodetection element 1012.

The frame memory 1014 temporarily records image data on still images or moving images captured by the image pickup system. The display 1015 is a liquid crystal display or an organic EL display and displays still images or moving images captured by the image pickup system. The operation system 1016 issues operation commands in terms of the various functions of the electronic apparatus 1000 in response to user inputs.

The auxiliary memory 1017 is a storage medium including a semiconductor memory such as a flash memory and records image data on still images or moving images captured by the image pickup system. The communication I/F 1018 includes a communication module compatible with predetermined communication methods and transmits image data on still images or moving images captured by the image pickup system to other apparatuses over a network.

The power supply system 1019 appropriately supplies, as operating power sources, various power sources to the CPU 1010, the DSP 1013, the frame memory 1014, the display 1015, the operation system 1016, the auxiliary memory 1017, and the communication I/F 1018.

Note that embodiments of the present disclosure are not limited to the embodiments described above, and various changes can be made within a range not departing from the gist of the present disclosure.

The effects described herein are merely exemplary and are not limiting, and other effects may be provided. Note that, herein, “on-chip micro lens” may be read as “on-chip lens (OCL).”

Further, the present disclosure can take the following configurations.

(1)

A photodetector including:
multiple pixels each having a photoelectric conversion region; and
an on-chip micro lens disposed for the pixels,
in which, in at least a part of a pixel section including n×n pixels, a first on-chip micro lens and a second on-chip micro lens different from the first on-chip micro lens are disposed.
   (2)

The photodetector according to (1) above,
in which the pixel section includes the n×n pixels corresponding to color filters of a same color in an n×n array,
the pixel section has an n×n-OCL structure at least in part, the n×n-OCL structure being a structure in which a single on-chip micro lens is shared by n×n pixels, and
another on-chip micro lens is disposed in a gap portion that is a region which is near the on-chip micro lens for the n×n-OCL structure and in which the on-chip micro lens is absent.
   (3)

The photodetector according to (2) above,
in which the pixel section includes 4×4 pixels corresponding to color filters of the same color in a 4×4 array,
the pixel section includes pixel sections all or some of which have a 4×4-OCL structure that is a structure in which a single on-chip micro lens is shared by 4×4 pixels, and
the another on-chip micro lens is disposed to fill the gap portion.
   (4)

The photodetector according to (3) above, in which the another on-chip micro lens includes on-chip micro lenses all or some of which are inner lenses.

(5)

The photodetector according to (3) above,
in which the pixel section has a 1×1-OCL structure in part, the 1×1-OCL structure being a structure in which a single on-chip micro lens is disposed for a single pixel, and
the 4×4-OCL structure is combined with the 1×1-OCL structure.
   (6)

The photodetector according to (5) above, in which the pixel section includes a phase difference pixel for acquiring phase difference information.

(7)

The photodetector according to (5) or (6) above, in which the another on-chip micro lens includes on-chip micro lenses all or some of which are inner lenses.

(8)

The photodetector according to (5) above,
in which the pixel section with the 4×4-OCL structure includes pixel sections of different colors,
the gap portion includes an inter-different-color gap portion that is located between the pixel sections of different colors when the 4×4-OCL structure is combined with the 1×1-OCL structure, and
still another on-chip micro lens is disposed in the inter-different-color gap portion.
   (9)

The photodetector according to (5) above, in which the pixel section includes pixel sections corresponding to a specific color, all or some of the pixel sections having the 4×4-OCL structure.

(10)

The photodetector according to (9) above,
in which the pixel section includes pixel sections provided with a color filter configured to transmit a wavelength corresponding to green (G), all or some of the pixel sections having the 4×4-OCL structure, and
the another on-chip micro lens is disposed in the gap portion located near the 4×4-OCL structure.
   (11)

The photodetector according to (10) above, in which the another on-chip micro lens includes on-chip micro lenses all or some of which are inner lenses.

(12)

The photodetector according to (9) above,
in which the pixel section includes pixel sections provided with a color filter configured to transmit a wavelength corresponding to red (R), all or some of the pixel sections having the 4×4-OCL structure, and
the another on-chip micro lens is disposed in the gap portion located near the 4×4-OCL structure.
   (13)

The photodetector according to (12) above, in which the another on-chip micro lens includes on-chip micro lenses all or some of which are inner lenses.

(14)

The photodetector according to (9) above,
in which the pixel section includes pixel sections provided with a color filter configured to transmit a wavelength corresponding to blue (b), all or some of the pixel sections having the 4×4-OCL structure, and
the another on-chip micro lens is disposed in the gap portion located near the 4×4-OCL structure.
   (15)

The photodetector according to (14) above, in which the another on-chip micro lens includes on-chip micro lenses all or some of which are inner lenses.

(16)

The photodetector according to (1) above,
in which the pixel section includes the n×n pixels corresponding to color filters of a same color in an n×n array, and,
in the pixel section, a pixel surrounded by a pixel of the same color has an on-chip micro lens arrangement in a structure different from that of a pixel adjacent to a pixel of a different color.
   (17)

The photodetector according to (16) above,
in which the pixel section includes 4×4 pixels corresponding to color filters of the same color in a 4×4 array, and,
in the pixel section, the pixel surrounded by the pixel of the same color has a 2×2-OCL structure in which a single on-chip micro lens is shared by 2×2 pixels, and the pixel adjacent to the pixel of the different color has a 1×1-OCL structure in which a single on-chip micro lens is disposed for a single pixel.
   (18)

The photodetector according to (17) above, in which a height of the on-chip micro lens for the 2×2-OCL structure is greater than a height of the on-chip micro lens for the 1×1-OCL structure.

(19)

The photodetector according to (17) above, in which a width of a separation portion for separating color filters in a 2×2 array corresponding to the 2×2-OCL structure from surroundings is greater than a width of a separation portion for separating color filters in a 1×1 array corresponding to the 1×1-OCL structure from surroundings.

(20)

The photodetector according to any of (17) to (19) above, in which the color filters include at least any of a color filter configured to transmit a wavelength corresponding to red (R), a color filter configured to transmit a wavelength corresponding to green (G), or a color filter configured to transmit a wavelength corresponding to blue (B).

(21)

The photodetector according to any of (17) to (20) above, in which the color filters include at least any of a color filter configured to transmit a wavelength corresponding to cyan (C), a color filter configured to transmit a wavelength corresponding to magenta (M), or a color filter configured to transmit a wavelength corresponding to yellow (Y).

(22)

The photodetector according to any of (17) to (21) above, in which the pixel section includes pixel sections at least some of which are phase difference pixel sections configured to acquire phase difference information.

(23)

The photodetector according to (16) above,
in which the pixel section includes 4×4 pixels corresponding to color filters of the same color in a 4×4 array, and,
in the pixel section, the pixel surrounded by the pixel of the same color has a 2×2-OCL structure in which a single on-chip micro lens is shared by 2×2 pixels, and the pixel adjacent to the pixel of the different color has a 1×1-OCL structure in which a single on-chip micro lens is disposed for a single pixel, a 1×2-OCL structure in which a single on-chip micro lens is shared by 1×2 pixels, or a 2×1-OCL structure in which a single on-chip micro lens is shared by 2×1 pixels.
   (24)

The photodetector according to (16) above,
in which the pixel section includes 4×4 pixels corresponding to color filters of the same color in a 4×4 array, and,
in the pixel section, the pixel surrounded by the pixel of the same color has a 1×2-OCL structure in which a single on-chip micro lens is shared by 1×2 pixels or a 2×1-OCL structure in which a single on-chip micro lens is shared by 2×1 pixels, and the pixel adjacent to the pixel of the different color has a 1×1-OCL structure in which a single on-chip micro lens is disposed for a single pixel.
   (25)

The photodetector according to any of (17) to (24) above, in which the pixel section includes pixel sections that are different in at least either a position or a size of at least one of structures of the on-chip micro lens, the color filter, and a separation portion configured to separate the color filter.

(26)

An electronic apparatus including:
a photodetector mounted thereon,
the photodetector including
   multiple pixels each having a photoelectric conversion region, and
   an on-chip micro lens disposed for the pixels,
in which, in at least a part of a pixel section including n×n pixels, a first on-chip micro lens and a second on-chip micro lens different from the first on-chip micro lens are disposed.

### REFERENCE SIGNS LIST

10: Solid-state image pickup device
100: Pixel
110: Phase difference pixel
111: Silicon substrate
112: Pixel separation section
121: Color filter
122: CF separation section
131, 132, 133, 134: On-chip micro lens
141, 143, 144: On-chip micro lens
142: Inner lens
200: Pixel section
211: Silicon substrate
212: Pixel separation section
221: Color filter
222: CF separation section
231, 232, 233, 234, 235: On-chip micro lens
1000: Electronic apparatus
1012: Photodetection element

What is claimed is:

1. A photodetector, comprising:
multiple pixels each having a photoelectric conversion region; and
an on-chip micro lens disposed for the pixels,
wherein, in at least a part of a pixel section including n×n pixels, a first on-chip micro lens and a second on-chip micro lens different from the first on-chip micro lens are disposed.

2. The photodetector according to claim 1,
wherein the pixel section includes the n×n pixels corresponding to color filters of a same color in an n×n array,
the pixel section has an n×n-OCL structure at least in part, the n×n-OCL structure being a structure in which a single on-chip micro lens is shared by n×n pixels, and another on-chip micro lens is disposed in a gap portion that is a region which is near the on-chip micro lens for the n×n-OCL structure and in which the on-chip micro lens is absent.

3. The photodetector according to claim 2,
wherein the pixel section includes 4×4 pixels corresponding to color filters of the same color in a 4×4 array,
the pixel section includes pixel sections all or some of which have a 4×4-OCL structure that is a structure in which a single on-chip micro lens is shared by 4×4 pixels, and
the another on-chip micro lens is disposed to fill the gap portion.

4. The photodetector according to claim 3, wherein the another on-chip micro lens includes on-chip micro lenses all or some of which are inner lenses.

5. The photodetector according to claim 3,
wherein the pixel section has a 1×1-OCL structure in part, the 1×1-OCL structure being a structure in which a single on-chip micro lens is disposed for a single pixel, and
the 4×4-OCL structure is combined with the 1×1-OCL structure.

6. The photodetector according to claim 5, wherein the pixel section includes a phase difference pixel for acquiring phase difference information.

7. The photodetector according to claim 5, wherein the another on-chip micro lens includes on-chip micro lenses all or some of which are inner lenses.

8. The photodetector according to claim 5,
wherein the pixel section with the 4×4-OCL structure includes pixel sections of different colors,
the gap portion includes an inter-different-color gap portion that is located between the pixel sections of different colors when the 4×4-OCL structure is combined with the 1×1-OCL structure, and
still another on-chip micro lens is disposed in the inter-different-color gap portion.

9. The photodetector according to claim 5, wherein the pixel section includes pixel sections corresponding to a specific color, all or some of the pixel sections having the 4×4-OCL structure.

10. The photodetector according to claim 9,
wherein the pixel section includes pixel sections provided with a color filter configured to transmit a wavelength corresponding to green (G), all or some of the pixel sections having the 4×4-OCL structure, and
the another on-chip micro lens is disposed in the gap portion located near the 4×4-OCL structure.

11. The photodetector according to claim 10, wherein the another on-chip micro lens includes on-chip micro lenses all or some of which are inner lenses.

12. The photodetector according to claim 9,
wherein the pixel section includes pixel sections provided with a color filter configured to transmit a wavelength corresponding to red (R), all or some of the pixel sections having the 4×4-OCL structure, and
the another on-chip micro lens is disposed in the gap portion located near the 4×4-OCL structure.

13. The photodetector according to claim 12, wherein the another on-chip micro lens includes on-chip micro lenses all or some of which are inner lenses.

14. The photodetector according to claim 9,
wherein the pixel section includes pixel sections provided with a color filter configured to transmit a wavelength corresponding to blue (b), all or some of the pixel sections having the 4×4-OCL structure, and
the another on-chip micro lens is disposed in the gap portion located near the 4×4-OCL structure.

15. The photodetector according to claim 14, wherein the another on-chip micro lens includes on-chip micro lenses all or some of which are inner lenses.

16. The photodetector according to claim 1,
wherein the pixel section includes the n×n pixels corresponding to color filters of a same color in an n×n array, and,
in the pixel section, a pixel surrounded by a pixel of the same color has an on-chip micro lens arrangement in a structure different from that of a pixel adjacent to a pixel of a different color.

17. The photodetector according to claim 16,
wherein the pixel section includes 4×4 pixels corresponding to color filters of the same color in a 4×4 array, and,
in the pixel section, the pixel surrounded by the pixel of the same color has a 2×2-OCL structure in which a single on-chip micro lens is shared by 2×2 pixels, and the pixel adjacent to the pixel of the different color has a 1×1-OCL structure in which a single on-chip micro lens is disposed for a single pixel.

18. The photodetector according to claim 17, wherein a height of the on-chip micro lens for the 2×2-OCL structure is greater than a height of the on-chip micro lens for the 1×1-OCL structure.

19. The photodetector according to claim 17, wherein a width of a separation portion for separating color filters in a 2×2 array corresponding to the 2×2-OCL structure from surroundings is greater than a width of a separation portion for separating color filters in a 1×1 array corresponding to the 1×1-OCL structure from surroundings.

20. The photodetector according to claim 17, wherein the color filters include at least any of a color filter configured to transmit a wavelength corresponding to red (R), a color filter configured to transmit a wavelength corresponding to green (G), or a color filter configured to transmit a wavelength corresponding to blue (B).

21. The photodetector according to claim 17, wherein the color filters include at least any of a color filter configured to transmit a wavelength corresponding to cyan (C), a color filter configured to transmit a wavelength corresponding to magenta (M), or a color filter configured to transmit a wavelength corresponding to yellow (Y).

22. The photodetector according to claim 17, wherein the pixel section includes pixel sections at least some of which are phase difference pixel sections configured to acquire phase difference information.

23. The photodetector according to claim 16,
wherein the pixel section includes 4×4 pixels corresponding to color filters of the same color in a 4×4 array, and,
in the pixel section, the pixel surrounded by the pixel of the same color has a 2×2-OCL structure in which a single on-chip micro lens is shared by 2×2 pixels, and the pixel adjacent to the pixel of the different color has a 1×1-OCL structure in which a single on-chip micro lens is disposed for a single pixel, a 1×2-OCL structure in which a single on-chip micro lens is shared by 1×2 pixels, or a 2×1-OCL structure in which a single on-chip micro lens is shared by 2×1 pixels.

24. The photodetector according to claim 16,
wherein the pixel section includes 4×4 pixels corresponding to color filters of the same color in a 4×4 array, and,
in the pixel section, the pixel surrounded by the pixel of the same color has a 1×2-OCL structure in which a single on-chip micro lens is shared by 1×2 pixels or a 2×1-OCL structure in which a single on-chip micro lens is shared by 2×1 pixels, and the pixel adjacent to the pixel of the different color has a 1×1-OCL structure in which a single on-chip micro lens is disposed for a single pixel.

25. The photodetector according to claim 17, wherein the pixel section includes pixel sections that are different in at least either a position or a size of at least one of structures of the on-chip micro lens, the color filter, and a separation portion configured to separate the color filter.

26. An electronic apparatus, comprising:
a photodetector mounted thereon,
the photodetector including
multiple pixels each having a photoelectric conversion region, and
an on-chip micro lens disposed for the pixels,
wherein, in at least a part of a pixel section including n×n pixels, a first on-chip micro lens and a second on-chip micro lens different from the first on-chip micro lens are disposed.
